(19) United States
(12) Patent Application Publication
(10) Pub. No.: US 2026/0262281 A1
(43) Pub. Date: Sep. 3, 2026

(54) AVALANCHE PHOTODIODE WITH A DIFFUSED EXTENSION LAYER

(71) Applicant: TEXAS INSTRUMENTS INCORPORATED, Dallas, TX (US)

(72) Inventors: Gerd Schuppener, Allen, TX (US); Henry Litzmann Edwards, Garland, TX (US); Wenjuan Fan, Allen, TX (US); Srinath Ramaswamy, Murphy, TX (US)

(21) Appl. No.: 19/068,851

(22) Filed: Mar. 3, 2025

(51) Int. Cl. H10D 84/80; H10D 30/01; H10D 84/01; H10F 39/10

(52) U.S. Cl. CPC H10D 84/80; H10D 30/0281; H10D 84/0156; H10D 84/0191; H10F 39/103

(57) ABSTRACT

A semiconductor device includes a first semiconductor layer of a first type, a second semiconductor layer of a second type on the first semiconductor layer, a region of the first type at a first side of the second semiconductor layer and coupled to a first area of the first semiconductor layer, a first region of the second type on the region of the first type, and a second region of the second type at a second side of the second semiconductor layer, the second region of the second type being more heavily doped than the first region of the second type. In some examples, the semiconductor device and a laterally-diffused metal-oxide-semiconductor (LDMOS) circuit are monolithically formed on a same semiconductor substrate.

### BACKGROUND

Photodiodes may convert a light signal into an electrical signal (e.g., photocurrent) that represents at least the intensity or power of the light signal. For example, an avalanche photodiode (APD) may use avalanche multiplication of photo-generated charge carriers caused by impact ionization to achieve photocurrent multiplication and improve gain and sensitivity. An APD may include a multiplication layer in a PN or PIN diode that is reversely biased. The multiplication layer may have a high electric field (e.g., close to breakdown) under the reverse bias condition, such that charge carriers generated by light absorption may gain sufficient energy to impact atoms in the multiplication layer to generate more carriers through impact ionization, thereby achieving avalanche multiplication of charge carriers.

### SUMMARY

This summary is provided to introduce examples of disclosed concepts in a simplified form, which are further described below in the Detailed Description including the drawings provided.

According to certain aspects, an integrated circuit may include a first semiconductor layer; a second semiconductor layer on the first semiconductor layer, the second semiconductor layer is more lightly doped than the first semiconductor layer; an avalanche photodiode (APD) in a first region of the second semiconductor layer; and a laterally-diffused metal-oxide-semiconductor (LDMOS) circuit in a second region of the second semiconductor layer.

According to certain aspects, a semiconductor device may include a first semiconductor layer of a first type, a second semiconductor layer of a second type on the first semiconductor layer, a region of the first type at a first side of the second semiconductor layer and coupled to a first area of the first semiconductor layer, a first region of the second type on the region of the first type, and a second region of the second type at a second side of the second semiconductor layer, the second region of the second type being more heavily doped than the first region of the second type.

According to certain aspects, a method may include forming, in a semiconductor layer of a first type, a first region of a second type, the first region including first dopants of the second type; doping a second region in the first region of the second type with second dopants of the second type to form the second region of the second type, the second dopants of the second type having a different diffusion property from the first dopants of the second type; growing an epitaxial layer of the first type over the semiconductor layer and the second region, wherein the second dopants of the second type in the second region at least partially diffuse into the epitaxial layer during the growing; forming a first region of the first type in the epitaxial layer above the second region of the epitaxial layer; and forming a second region of the first type in a the epitaxial layer, the second region of the first type being spaced from and more heavily doped than the first region of the first type.

The foregoing summary outlines rather broadly various features of examples of the present disclosure so that the following detailed description may be better understood. Additional features and advantages of such examples will be described hereinafter. This summary is neither intended to identify key or essential features of the claimed subject matters, nor is it intended to be used in isolation to determine the scope of the claimed subject matters. The subject matters should be understood by reference to appropriate portions of the entire specification of this disclosure, any or all drawings, and each claim. The foregoing, together with other features and examples, will be described in more detail below in the following specification, claims, and accompanying drawings.

### BRIEF DESCRIPTION OF THE DRAWINGS

Illustrative examples are described in detail below with reference to the following figures.

FIG. 1A is a cross-sectional view of an example of an avalanche photodiode (APD).

FIG. 1B is a cross-sectional view of a region of an example of an APD.

FIG. 1C is a diagram illustrating an example of an impurity concentration profile of an APD.

FIG. 2A (including FIGS. 2A-1 and 2A-2) is a cross-sectional view of an example of an integrated circuit including an APD and a complementary metal-oxide-semiconductor (CMOS) circuit.

FIG. 2B is an example of a schematic of the integrated circuit of FIG. 2A.

FIG. 3A and FIG. 3B are cross-sectional views of an example of an integrated circuit including an APD and a laterally-diffused metal-oxide-semiconductor (LDMOS) circuit.

FIG. 4 is a flowchart illustrating an example of a process of fabricating an APD.

FIGS. 5A, 5B, 5C, 5D, 5E, 5F, 5G, and 5H are schematics of cross-sectional views of a semiconductor device in the example process of FIG. 4.

FIG. 6A is a diagram illustrating n-dopant and p-dopant concentration profiles of an example of an APD.

FIG. 6B is a diagram illustrating an impurity concentration profile of the net dopants in the example of the APD of FIG. 6A.

FIG. 7 is a flowchart illustrating another example of a process of fabricating an APD.

FIGS. 8A, 8B, 8C, 8D, 8E, 8F, 8G, and 8H are schematics of cross-sectional views of a semiconductor device in the example process of FIG. 7.

FIG. 9A is a diagram illustrating n-dopant and p-dopant concentration profiles of an example of an APD.

FIG. 9B is a diagram illustrating an impurity concentration profile of the net dopants in the example of the APD of FIG. 9A.

FIG. 10A is a cross-sectional view of an example of an APD.

FIG. 10B is a diagram illustrating an example of an impurity concentration profile of an example of the APD shown in FIG. 10A.

FIG. 11A and FIG. 11B are cross-sectional views of an example of an integrated circuit including an APD and an LDMOS circuit.

FIG. 12 is a flowchart illustrating an example of a process of fabricating an APD.

FIGS. 13A, 13B, 13C, 13D, 13E, 13F, 13G, 13H, and 13I illustrate cross-sectional views of a semiconductor device in the example process of FIG. 12.

The drawings and accompanying detailed description are provided for understanding of features of various examples and do not limit the scope of the appended claims. The examples illustrated in the drawings and described in the accompanying detailed description may be readily utilized as a basis for modifying or designing other examples that are within the scope of the appended claims. One skilled in the art will readily recognize from the following description that alternative examples of the structures and methods illustrated may be employed without departing from the principles, or benefits touted, of this disclosure. Identical reference numerals may be used, where possible, to designate identical elements that are common among drawings. The figures are drawn to clearly illustrate the relevant elements or features and are not necessarily drawn to scale.

### DETAILED DESCRIPTION

The present disclosure relates generally to integrated circuits including integrated photodiodes, such as avalanche photodiodes (APDs). According to some examples, a monolithic integrated circuit may include an APD and a metal-oxide-semiconductor (MOS) circuit, such as a complementary metal-oxide-semiconductor (CMOS) circuit and/or a laterally-diffused metal-oxide-semiconductor (LDMOS) circuit. The APD may be fabricated using processes that are compatible with a bipolar-CMOS-double-diffused MOS (DMOS) process (BCD process). For example, the multiplication layer of the APD may be formed by implanting dopants after epitaxial layer growth, or by implanting dopants before epitaxial layer growth and annealing after the epitaxial layer growth. In some examples, the multiplication layer may form a PN junction with a buried layer through an extension layer formed by implanting dopants into the buried layer and allowing the dopants in the buried layer to diffuse into an epitaxial layer grown after the implanting. Various examples are described herein, including devices, circuits, systems, methods, processes, materials, and the like.

An avalanche photodiode (APD) is a type of photodiode that utilizes impact ionization to achieve charge carrier and photocurrent multiplication, thereby improving the gain and sensitivity for photodetection. An avalanche photodiode may include a PN or PIN diode structure that includes an absorption layer and a multiplication layer between an anode (e.g., a heavily doped p-type (p⁺) region) and a cathode (e.g., a heavily doped n-type (n⁺) region). When the avalanche photodiode operates under a reverse bias voltage between the anode and the cathode (e.g., the cathode is biased at a more positive voltage than the anode), photons entering the photodiode may be absorbed in the absorption layer to generate charge carriers, such as electron-hole pairs. The reverse bias voltage may create an electric field between the anode and the cathode, and the electric field may cause free electrons to move towards the more positively biased cathode and the holes to move towards the anode. When the reverse bias voltage is high (e.g., close to the breakdown voltage of the photodiode), the electric field between the cathode and the anode may be high, and thus the charge carriers (electrons and holes) generated in the absorption layer may be accelerated to have high energy. The high-energy charge carriers entering the multiplication layer may impact atoms in the multiplication layer to create additional electron-hole pairs by impact ionization. Therefore, the photocurrent of the photodiode may be amplified, and thus the sensitivity of the avalanche photodiode in detecting and measuring photons can be improved compared with a photodiode that may not have carrier multiplication capability.

In one example, the high electric-field multiplication layer in an APD may be a p-type layer formed in a portion of an intrinsic layer (i-layer) or a lightly doped p-type (p⁻) layer that is close to a heavily doped n-type (n⁺) layer (e.g., a cathode) in a PN or PIN diode structure, thereby forming a p⁺/p⁻/p/n⁺ or p⁺/i/p/n⁺ device structure. The doping concentration profile, thickness, and location of the multiplication layer within the APD may affect performance of the APD, such as the breakdown voltage and bandwidth of the APD. Some techniques used in bipolar CMOS (BiCMOS) technologies to optimize the performance of electrical devices may not yield target performance of optoelectronic devices, such as APDs. Some techniques that may improve the performance of optoelectronic devices may be difficult to be incorporated into existing BiCMOS technologies (e.g., due to the high implant energy used), without impacting the overall thermal budget and electrical device performance. Therefore, it can be difficult to integrate APDs with CMOS, BiCMOS, or LDMOS circuits.

For example, it can be difficult to precisely control the dopant concentration profile, thickness, and location (or depth) of the multiplication layer in the semiconductor layer stack of the p⁺/p⁻/p/n⁺ or p⁺/i/p/n⁺ device structure that may be relatively thick (e.g., more than a few microns). In III-V compound photodiodes, the layer stack may be formed by epitaxial growth of the layers, where the impurity may be incorporated into the epitaxial layers and the impurity concentration in the layers may be controlled during the epitaxial growth. However, such techniques may not be suitable for fabricating silicon-based photodiodes. To improve performance of silicon-based photodiodes, the silicon process flow (e.g., including epitaxy, implant, and diffusion processes) may need to be customized, which may not be compatible with existing (Bi)CMOS processing flows for electrical circuits. In some examples, the multiplication layer may be formed by implanting dopants after the epitaxial growth. However, in order to form a multiplication layer deep under (e.g., more than a few microns below) the surface of the epitaxial layer, high-energy implants may be used, which may be difficult or expensive to achieve and may also cause damages to the crystalline structure of the semiconductor layer that may degrade the performance and/or reliability of the APD devices.

According to some examples, an APD and an electrical circuit (e.g., a CMOS circuit or an LDMOS circuit) may be fabricated on a same die using a same fabrication process. In one example, after forming a heavily doped n⁺ buried layer (NBL) that includes an n-type dopant (e.g., antimony (Sb)), a p-type dopant (e.g., boron (B)) that has a different diffusion property (e.g., a higher diffusion constant) than the n-type dopant may be implanted into a region of the n⁺ buried layer. An intrinsic or lightly p-doped epitaxial layer may be grown over the n⁺ buried layer. During the epitaxial growth of the intrinsic or lightly p-doped epitaxial layer and/or subsequent annealing processes, the p-type dopant having the higher diffusion constant may diffuse from the n⁺ buried layer into the intrinsic or lightly doped epitaxial layer at a rate faster than the n-type dopant, and thus may have a higher concentration than the n-type dopant in a region of the intrinsic or lightly p-doped epitaxial layer adjacent to the n⁺ buried layer. As such, the region of the intrinsic or lightly p-doped epitaxial layer adjacent to the n⁺ buried layer may have a higher net p-dopant concentration than the rest of the intrinsic or lightly p-doped epitaxial layer, and thus a p-doped region adjacent to the n⁺ buried layer may be formed to function as the multiplication layer. Therefore, the APD can be fabricated without performing high-energy p-dopant implanting. By selecting the proper dose and energy for implanting the p-type dopant, a pn⁺ junction with a target impurity concentration profile and layer thicknesses may be formed to achieve the target APD performance. In another example, the multiplication layer may be formed by high-energy implanting from the top of the intrinsic or lightly doped epitaxial layer, and various techniques for mitigating the damages to the crystalline structure of the semiconductor layer caused by the high-energy implanting may be used to improve the performance and/or reliability of the APD devices.

In yet another example, after forming an n⁺ buried layer that includes a first n-type dopant (e.g., Sb), a second n-type dopant (e.g., phosphorus (P)) that has a higher diffusion constant than the first n-type dopant may be implanted into a region of the n⁺ buried layer. An intrinsic or lightly p-doped epitaxial layer may be grown over the n⁺ buried layer. During the epitaxial growth of the intrinsic or lightly p-doped epitaxial layer and/or the subsequent annealing processes, the second n-type dopant having the higher diffusion constant may diffuse from the region of the n⁺ buried layer into the intrinsic or lightly p-doped epitaxial layer at a rate faster than the first n-type dopant. Therefore, a region of the intrinsic or lightly p-doped epitaxial layer adjacent to the n⁺ buried layer may have a higher concentration of n-type dopants (e.g., mostly the second n-type dopant) than p-type dopants. As such, the region of the intrinsic or lightly p-doped epitaxial layer adjacent to the n⁺ buried layer may become an n-doped extension region. A subsequent p-type implanting (e.g., using B) may be performed from the top of the intrinsic or lightly p-doped epitaxial layer to form the multiplication layer of an APD. The multiplication layer may form a junction with the n-doped extension region. Since the p-type dopants are not implanted into a region adjacent to the n⁺ buried layer that may be deep under the top surface of the intrinsic or lightly p-doped epitaxial layer, the energies of the p-type dopants may be low, and thus may be easy to achieve and may cause less damage to the crystalline structure of the semiconductor layer. By selecting the proper dose and energy for implanting the second n-type dopant and/or the p-type dopant, an n⁺/n/p junction with the target impurity concentration profile and layer thicknesses and locations may be formed to achieve the desired APD performance.

Therefore, techniques disclosed herein may allow more precise control of the impurity concentration profile and layer thicknesses and locations of the APD structure. In addition, techniques disclosed herein may include minimal modification to existing bipolar-CMOS DMOS (BCD) processes (e.g., including one additional masked implanting process), and thus are fully compatible with existing BCD processes and do not significantly increase the cost and difficulty of the fabrication. Techniques disclosed herein may not degrade the performance and reliability of the APD, and may not impact the performance of any other circuits on the same die or wafer with the APD. As such, techniques disclosed herein allow monolithic integration of APD and CMOS/BiCMOS/LDMOS circuits. Techniques disclosed herein can be used to form p⁺/p⁻/p/n⁺ APD structures, n⁺/n⁻/n/p⁺ APD structures, p⁺/i/p/n⁺ APD structures, n⁺/i/n/p⁺ APD structures, or other APD structures.

Various features are described hereinafter with reference to the figures. An illustrated example may not have all the aspects or advantages shown. An aspect or an advantage described in conjunction with a particular example is not necessarily limited to that example and can be practiced in any other examples even if not so illustrated or if not so explicitly described. Further, methods described herein may be described in a particular order of operations, but other methods according to other examples may be implemented in various other orders (e.g., including different serial or parallel performance of various operations) with more or fewer operations.

Various examples are described herein. Although the specific examples may illustrate various aspects of the above generally described features, examples may incorporate any combination of the above generally described features (which are described in more detail in examples below). Three dimensional x-y-z axes are illustrated in some figures for ease of reference. Some cross-sectional views of various semiconductor devices herein may be general depictions to illustrate various aspects or concepts concerning such semiconductor devices. More specifically, some drain contact structures illustrated in cross-sectional views may not necessarily accurately depict a structure of such drain contact contacts, except to the extent described herein. The illustrations of those drain contact structures are to illustrate various aspects or concepts concerning those drain contact structures.

In the following description, for the purposes of explanation, specific details are set forth in order to provide a thorough understanding of examples of the disclosure. However, it will be apparent that various examples may be practiced without these specific details. For example, devices, systems, structures, assemblies, integrated circuits, and other components may be shown as components in block diagram form in order not to obscure the examples in unnecessary detail. In other instances, well-known devices, processes, systems, structures, and techniques may be shown without necessary detail in order to avoid obscuring the examples. The figures and description are not intended to be restrictive. The terms and expressions that have been employed in this disclosure are used as terms of description and not of limitation, and there is no intention in the use of such terms and expressions of excluding any equivalents of the features shown and described or portions thereof. The word “example” is used herein to mean “serving as an example, instance, or illustration.” Any example or design described herein as “example” is not necessarily to be construed as preferred or advantageous over other examples or designs.

As many other photodiodes, avalanche photodiodes (APDs) utilize the photoelectric effect of materials (e.g., semiconductor materials) to convert a light signal into an electrical signal. When a photon with energy greater than the bandgap of a semiconductor material is absorbed by the semiconductor material, an electron of the semiconductor material may gain sufficient energy to become a free electron, thereby generating an electron-hole pair. The electron and hole may be accelerated by an electric field applied through a reverse bias, leading to the generation of more and more electron-hole pairs through impact ionization. This avalanche effect results in a rapid multiplication of charge carriers, thereby significantly amplifying the initial photo-generated signal. Therefore, APDs may achieve a higher gain and sensitivity using the avalanche multiplication to improve the signal-to-noise ratio (SNR) (in particular, at low illumination), and may have low response time, enhanced stability, and compact size. Some APDs may also have superior performance in quantum efficiency, timing resolution, and spatial resolution. Therefore, APDs have been used in many applications (e.g., imaging) to achieve sensitive detection, rapid signal acquisition, and miniaturization.

Some APDs may have a PN junction structure including p and n layers. Some APDs may have a PN junction structure with multiple semiconductor layer stacks, such as a p⁺/i/p/n⁺ or p⁺/p⁻/p/n⁺ structure. Some APDs may have an anode and a cathode on opposite sides of a semiconductor layer stack. APDs made using planar integrated circuit (IC) technologies may have the anode and cathode on the same side of the semiconductor layer stack, where at least one of the anode or cathode may be connected to a corresponding semiconductor layer through a deep contact formed in the semiconductor layer stack. The semiconductor materials of the semiconductor layer stacks in APDs may include, for example, silicon (e.g., for detecting visible and near infrared light), germanium (e.g., for detecting infrared light), III-V compound semiconductors such as indium gallium arsenide (InGaAs) (e.g., for detecting near infrared and infrared light), gallium nitride (GaN) (e.g., for detecting ultraviolet light), and the like. Silicon-based avalanche photodiodes may be fabricated using technologies for making silicon-based electrical circuits, such as bipolar-CMOS-DMOS (BCD) processes, may be used for detecting visible light, may have better performance, and may be monolithically integrated with digital, analog, and/or radio-frequency (RF) circuits that may control or process data from the APD. Therefore, silicon-based APDs may be cost-effective and may reduce system size.

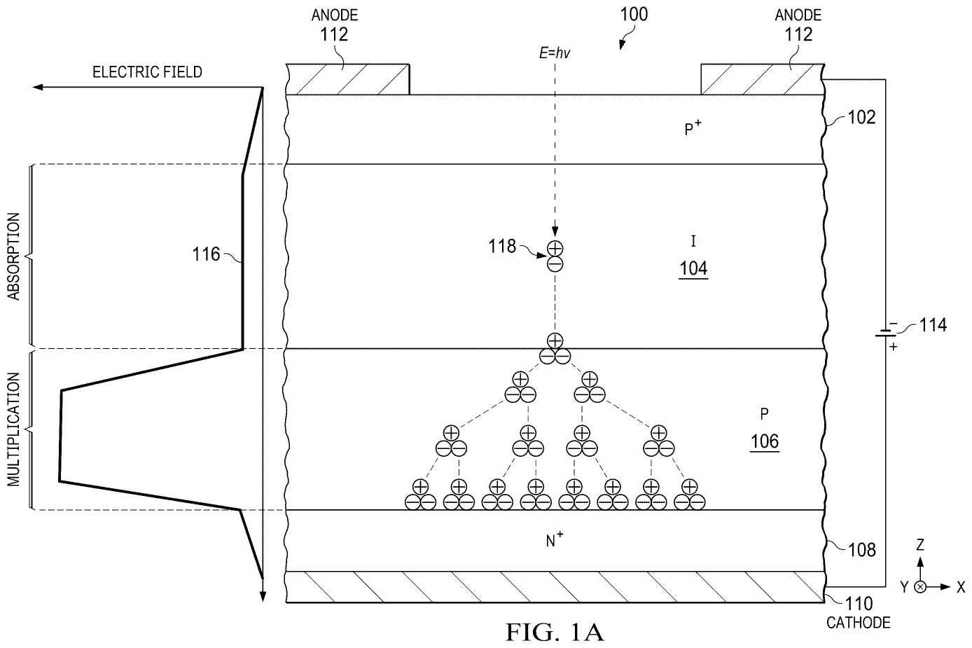

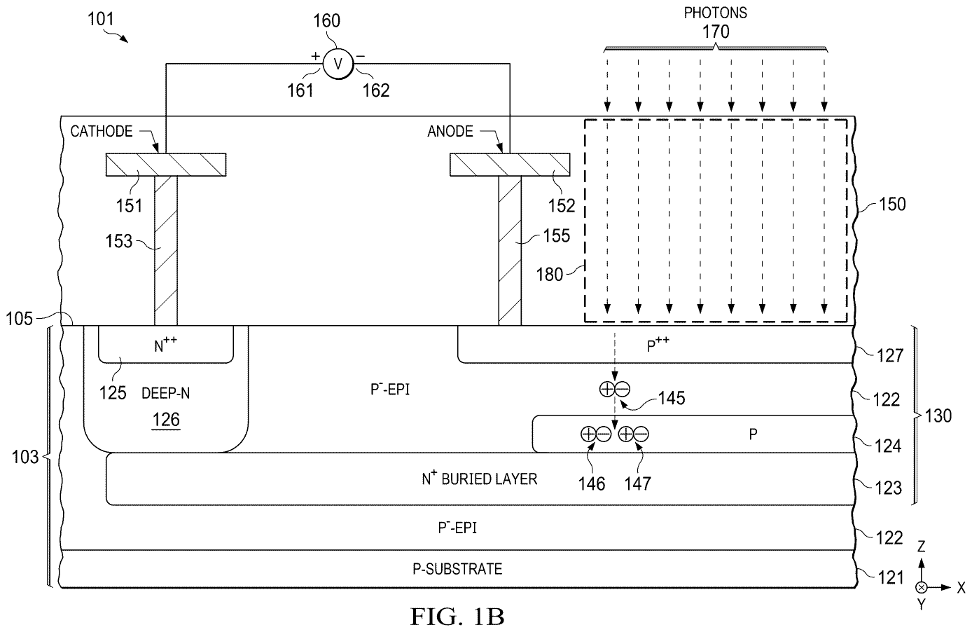

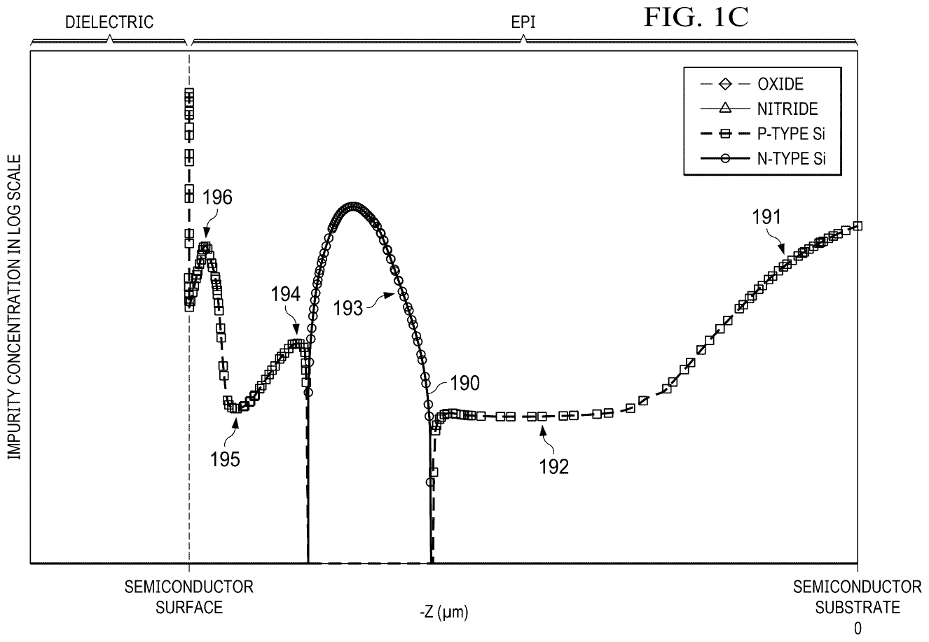

FIG. 1A is a cross-sectional view of an example of an APD 100. In the illustrated example, APD 100 may include a semiconductor layer stack formed by a heavily doped p-type (p⁺) layer 102, an intrinsic layer 104 (or a lightly p-doped layer), a p-doped layer 106, and a heavily doped n-type (n⁺) layer 108. The semiconductor layers may be fabricated by, for example, epitaxial growth using various vapor-phase, liquid-phase, or solid-phase epitaxy techniques, and may form a vertical p⁺/i/p/n⁺ junction structure. N-type dopants or p-type dopants may be incorporated into the semiconductor layers during the epitaxy or by post-growth implantation (e.g., ion implantation) or diffusion to form the n-type or p-type layers with the target dopant concentration. APD 100 may have a cathode 110 and an anode 112 on opposite sides of the junction structure, and may be reversely biased by a voltage source 114.

The dopant concentration profile of the semiconductor layer stack in APD 100 may be designed such that the highest electric field may be in the region of the p-n junction (e.g., p-doped layer 106) when APD 100 is reversely biased. For example, n⁺ layer 108 and p-doped layer 106 may be relatively highly doped, so the junction width of the depletion region between n⁺ layer 108 and p-doped layer 106 may be small, and thus the electric field at the junction may be high. When p-doped layer 106 has a lower doping concentration than n⁺ layer 108, the depletion region may be in p-doped layer 106 and may extend from the upper surface of n⁺ layer 108 through p-doped layer 106, intrinsic layer 104 to the lower edge of p⁺ layer 102 when APD 100 is reversely biased during normal operations. Intrinsic layer 104 (or a lightly p-doped layer) may have a higher thickness, and the electric field in intrinsic layer 104 may be low. A curve 116 in FIG. 1A illustrates an example of the electric field in the semiconductor layer stack of APD 100.

When intrinsic layer 104 (or a lightly p-doped layer) is illuminated by photons each with energy greater than the bandgap of the semiconductor material (e.g., silicon) of intrinsic layer 104, electron-hole pairs 118 may be generated by photo-absorption. The electrons and holes may drift towards the respective terminals (anode or cathode), due to the low electric field in intrinsic layer 104. Therefore, intrinsic layer 104 (or a lightly p-doped layer) may provide the absorption region or drift region. As free electrons generated in intrinsic layer 104 enter p-doped layer 106, their movement may be accelerated due to the high electric field. The accelerated electrons may accumulate sufficient energy to excite other electrons from the valence band, leading to a phenomenon known as avalanche amplification or multiplication of the photo-generated current. Therefore, p-doped layer 106 may be referred to as the multiplication region or gain region.

FIG. 1B is a cross-sectional view of a region (e.g., a half) of an example of an avalanche photodiode 101. APD 101 may be planar-based avalanche photodiode with the anode and cathode on a same side of a semiconductor substrate. In the illustrated example, avalanche photodiode 101 may include a semiconductor substrate 103 having a surface 105, and a dielectric layer 150 on surface 105. Dielectric layer 150 may include, for example, silicon dioxide or another dielectric material that may be transparent to light of interest. Semiconductor substrate 103 may include an active device formed by various semiconductor processing operations. For example, p-type dopants (e.g., boron) may be incorporated into undoped single crystal silicon of a silicon substrate by implantation or diffusion to form a p-type substrate 121. A lightly p-doped epitaxial layer (p⁺ epi layer) 122 may be grown on p-type substrate 121, for example, using epitaxy techniques mentioned above. A heavily doped n-type buried layer (n⁺ buried layer) 123 may be formed in a portion of p⁺ epi layer 122 through the incorporation (e.g., implantation) of n-type dopants, such as arsenic (As), antimony (Sb), and/or phosphorous (P). In some examples, p⁺ epi layer 122 may be formed by multiple epitaxial growth processes, where a first sublayer of p⁺ epi layer 122 may be grown first, n⁺ buried layer 123 may be formed at or near the surface of the first sublayer, and a second sublayer of p⁺ epi layer 122 may be grown on top of the first sublayer (and ⁺n buried layer 123), such that n⁺ buried layer 123 may be buried under the second sublayer of p⁻ epi layer 122. In some examples, p⁻ epi layer 122 may be formed by one epitaxial growth process, and n⁺ buried layer 123 may be formed in a region at a distance below the surface of p⁻ epi layer 122 by, for example, implantation of n-type dopants.

Within p⁻ epi layer 122 (e.g., the second sublayer of p⁻ epi layer 122), a p-type region 124 may be formed by, for example, implanting p-type dopants before or after the growth of the second sublayer of p⁻ epi layer 122, as described in more detail below, so that p-type region 124 and n⁺ buried layer 123 may form a PN junction. A deep n-type contact (or n contact) 126 (e.g., a deep n-well) may also be formed within a region of p⁻ epi layer 122, and may be in contact with edge regions of n⁺ buried layer 123. In some examples, deep n contact 126 may surround p-type region 124. A heavily doped n-type (n⁺⁺) region 125 may be formed within deep n contact 126. A heavily doped p-type (p⁺⁺) region 127 may be formed within another region of p⁻ epi layer 122. N⁺⁺ region 125 and p⁺⁺ region 127 may be used to form a low resistance cathode contact and a low resistance anode contact, respectively. Also, p⁺⁺ region 127, p⁻ epi layer 122, p-type region 124, and n⁺ buried layer 123 may be in a vertical layer stack (e.g., along the z axis that is in the surface-normal direction of surface 105) and may form a PN junction 130 (e.g., including a p⁺/p⁻/p and n⁺ junction structure) within avalanche photodiode 101. PN junction 130 may be oriented along the z axis of FIG. 1B (e.g., orthogonal to a major surface of semiconductor substrate 103), where p-type region 124 may be a multiplication (or gain) region, and p⁻ epi layer 122 may be an absorption (or drift) region. Deep n contact 126 and n⁺ buried layer 123 may be parts of a junction isolation structure providing isolation to p⁺⁺ region 127 and p-type region 124. As described above and below, during normal operations, PN junction 130 may be reversely biased at a voltage close to a breakdown voltage to facilitate impact ionization and avalanche multiplication.

Dielectric layer 150 may be deposited on surface 105 of semiconductor substrate 103. A cathode 151 and an anode 152 may be formed in dielectric layer 150. Cathode 151 may be electrically coupled to n⁺⁺ region 125 by one or more electrical interconnects 153 (e.g., a metal via). Similarly, anode 152 may be electrically coupled to p⁺⁺ region 127 by one or more electrical interconnects 155 (e.g., a metal via). Cathode 151, anode 152, and electrical interconnects 153 and 155 may be formed after the deposition of the dielectric layer 150, or may be formed after one or more sublayers of dielectric layer 150 are deposited. For example, electrical interconnects 153 and 155 may be formed by selectively etching one or more sublayers of dielectric layer 150 to form trenches and depositing a metal material into the trenches to form vias. Cathode 151 and anode 152 may be formed by, for example, depositing a metal layer on one or more sublayers of dielectric layer 150 and selectively etching the metal layer to pattern the metal layer.

Cathode 151 and anode 152 may be reversely biased by a voltage from a bias voltage circuit 160 (e.g., a voltage source). Bias voltage circuit 160 may include terminals 161 and 162. The voltage on terminal 161 may be positive relative to the voltage on terminal 162. Terminal 161 may be coupled to cathode 151, and terminal 162 may be coupled to anode 152. Accordingly, cathode 151 and n⁺⁺ region 125 may be at a positive potential with respect to anode 152 and p⁺⁺ region 127. The magnitude of the bias voltage can be high but below the breakdown voltage of avalanche photodiode 101. The magnitude of the electric field generated by reversely biasing the avalanche photodiode 101 may be high in p-type region 124 as described above. Even though not shown in FIG. 1B, bias voltage circuit 160 may include or may be connected to a current meter or a current-to-voltage converter for measuring the electrical signal generated by APD 101 upon exposure to light.

At least a portion 180 of dielectric layer 150 may be transparent to photons 170 of light within a wavelength range, such as visible light or infrared light. Therefore, photons 170 may pass through portion 180 of dielectric layer 150 and enter semiconductor substrate 103. When a photon 170 is absorbed in p⁻ epi layer 122, an electron-hole pair 145 may be generated. One or more electron-hole pairs 145 may be generated when one or more photons 170 are absorbed in p⁻ epi layer 122. The electric field generated by reversely biasing avalanche photodiode 101 may cause the charge carriers (e.g., electrons and holes) to move towards respective electrodes. For example, electrons may flow towards the more positively biased n⁺ buried layer 123, and thus may enter p-type region 124 where the magnitude of the electric field may be relatively high. Due to the relatively high electric field in p-type region 124, each charge carrier entering p-type region 124 may gain sufficient energy to generate one or more secondary electron-hole pairs (e.g., electron-hole pairs 146 and 147) through impact ionization. Each one of the initial secondary electron-hole pairs may, in turn, generate additional secondary electron-hole pairs, and so on. The holes created in p-type region 124 may flow towards p⁺⁺ region 127 and anode 152 that are negatively biased with respect to n⁺ buried layer 123 and cathode 151. In this manner, p-type region 124 may perform a multiplication function such that each photon 170 may result in multiple electron-holes pairs, thereby boosting the magnitude of the current from avalanche photodiode 101 in response to photons 170 incident on avalanche photodiode 101.

FIG. 1C is a diagram illustrating an example of an impurity concentration profile 190 of the net dopants in an APD, such as APD 101. The net dopant concentration may be the difference between the concentration of n-type dopants and the concentration of p-type dopants in a region. In FIG. 1C, the horizontal axis of the diagram corresponds to locations within the semiconductor substrate along the −z direction (e.g., opposite direction of the surface normal direction of surface 105) shown in FIG. 1B, where a position with a value 0 on the horizontal axis may correspond to a surface of semiconductor substrate 103. The vertical axis corresponds to the impurity (dopant) concentration (in log scale) in unit volume (e.g., cm⁻³). A region 191 of impurity concentration profile 190 shows the concentration of the p-type dopant (e.g., B) in p-type substrate 121. A region 192 of impurity concentration profile 190 shows the net concentration of the p-type dopant (e.g., B) in p⁻ epi layer 122 (e.g., a first sublayer of p⁻ epi layer 122). A region 193 of impurity concentration profile 190 shows the net concentration of the n-type dopant (e.g., As, Sb, and/or P) in n⁺ buried layer 123. A region 194 of impurity concentration profile 190 shows the net concentration of the p-type dopant (e.g., B) in p-type region 124. A region 195 of impurity concentration profile 190 shows the concentration of the p-type dopant (e.g., B) in p⁻ epi layer 122 (e.g., a second sublayer of p⁻ epi layer 122). A region 196 of impurity concentration profile 190 shows the concentration of the p-type dopant (e.g., B) in p⁺⁺ region 127.

Even though not shown in FIG. 1B, in some examples, semiconductor substrate 103 may be part of an integrated circuit that is fabricated using a BCD process and also includes CMOS, BiCMOS, and/or DMOS devices. The CMOS, BiCMOS, and/or DMOS devices may include power and high-voltage devices (e.g., transistors or diodes), analog devices (e.g., amplifiers and bandgap voltage references), digital circuits (e.g., memory and logic gates), passive devices (e.g., resistors, capacitors, or inductors), and the like, and may be used to control the operations of APD 101, process the electrical signal generated by APD 101, and perform other functions and data processing. In addition, even though FIG. 1B shows an APD having a p⁺/p⁻/p/n⁺ structure, an APD may have an n⁺/n⁻/n/p⁺ structure, a p⁺/i/p/n⁺ structure, or an n⁺/i/n/p⁺ structure in other examples, and may be fabricated using techniques disclosed herein.

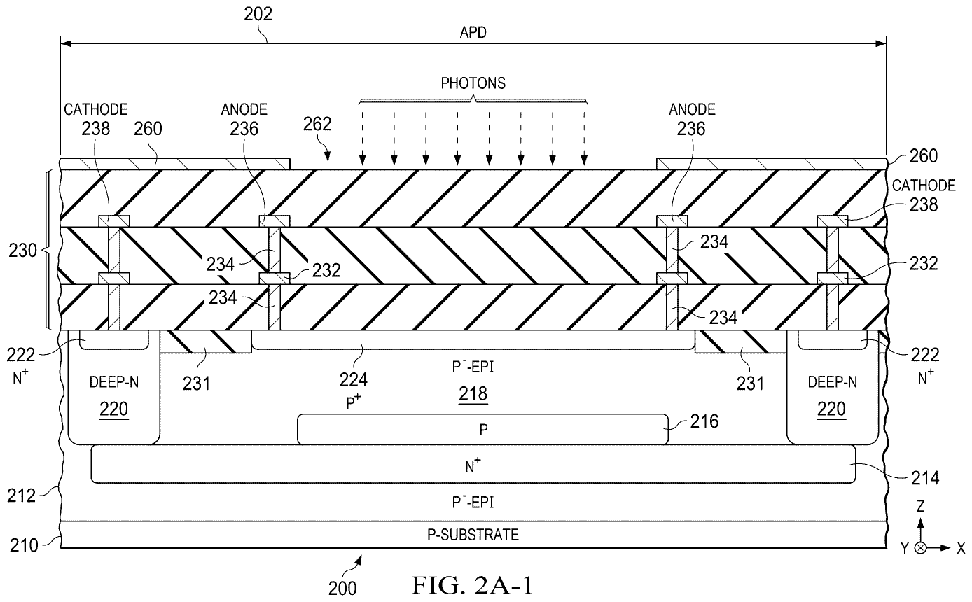

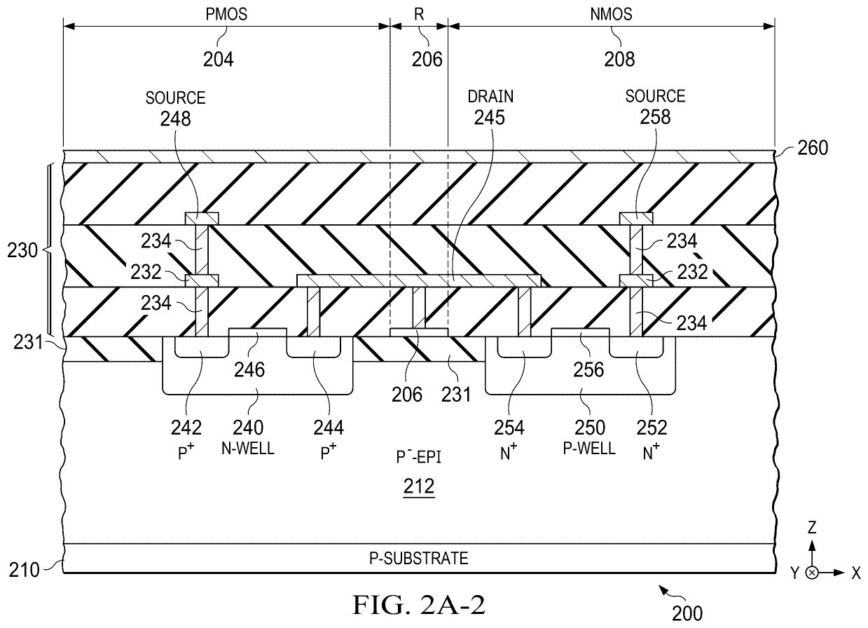

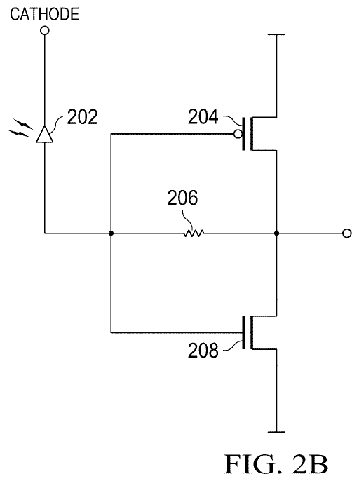

FIG. 2A (including FIGS. 2A-1 and 2A-2) is a cross-sectional view of an example of an integrated circuit 200 including an APD 202 (in FIG. 2A-1) and a CMOS circuit (in FIG. 2A-2). FIG. 2B is an example of a schematic of integrated circuit 200 of FIG. 2A. APD 202 may be similar to (or is an example of) APD 101 described above. In the illustrated example, the CMOS circuit may include a p-channel MOS (PMOS) transistor 204, an n-channel MOS (NMOS) transistor 208, and a resistor 206 formed by, for example, a polycrystalline silicon (polysilicon) layer that may also be used to form the gates of PMOS transistor 204 and NMOS transistor 208. PMOS transistor 204, NMOS transistor 208, and resistor 206 may form a transimpedance amplifier that may convert a current signal generated by APD 202 in response to an incident light signal into a voltage signal. For example, a terminal (e.g., anode or cathode) of APD 202 may be coupled to the input of the transimpedance amplifier (e.g., gates of PMOS transistor 204 and NMOS transistor 208 and a terminal of resistor 206). Resistor 206 may be a feedback resistor connected between the input and the output of the amplifier.

As illustrated in FIG. 2A, APD 202 and the CMOS circuit may be fabricated in a same die on a same substrate 210. In the illustrated example, substrate 210 may be a p-doped substrate formed by doping the single crystal silicon of a silicon substrate by implantation or diffusion of p-type dopants (e.g., boron, aluminum, gallium). A lightly p-doped epitaxial layer (p⁻ epi layer) 212 may be epitaxially grown on the p-doped substrate 210. A heavily doped n-type buried layer (n⁺ buried layer) 214 may be formed in a region of p⁻ epi layer 212 through the incorporation (e.g., implantation) of n-type dopants, such as As, Sb, or P. In one example, after p⁻ epi layer 212 is grown, n⁺ buried layer 214 may be formed at or near the surface of p⁻ epi layer 212, and another p⁻ epi layer 218 may be grown on top of p⁻ epi layer 212 (and n⁺ buried layer 214), such that n⁺ buried layer 214 may be buried under p⁻ epi layer 218. For examples, n⁺ buried layer 214 may be formed by heavily doping a region of p⁻ epi layer 212 at or near the surface of p⁻ epi layer 212 with an n-type dopant via implantation or diffusion. The n-type dopant may diffuse deeper into p⁻ epi layer 212 during a thermal annealing process and/or the epitaxial growth of p⁻ epi layer 218, and may partially diffuse into p⁻ epi layer 218 during the epitaxial growth of p⁻ epi layer 218 or a subsequent thermal annealing process, thereby forming n⁺ buried layer 214 in p⁻ epi layer 212 and/or p⁻ epi layer 218.

Within p⁻ epi layer 218, a p-type region 216 may be formed above n⁺ buried layer 214 (e.g., along the z-axis of FIG. 2A) by, for example, implanting p-type dopants before or after the growth of p⁻ epi layer 218, as described in more detail below, so that p-type region 216 and n⁺ buried layer 214 may form a PN junction. A deep n contact 220 (e.g., a deep n-well) may also be formed within a region of p⁻ epi layer 218, and may be in contact with edge regions of n⁺ buried layer 214. In some examples, deep n contact 220 may surround p-type region 216, and thus may, in combination with n⁺ buried layer 214), form a junction isolation structure that isolates p-type region 216 (which may function as the multiplication region of APD 202) and the absorption region (e.g., a region of p⁻ epi layer 218 above p-type region 216) of APD 202 from other circuits in integrated circuit 200. Therefore, APD 202 may have lower noise and better performance.

A heavily doped n-type (n⁺) region 222 may be formed within deep n contact 220. A heavily doped p-type (p⁺) region 224 may be formed within a region of p⁻ epi layer 218 above p-type region 216 by, for example, implanting a p-type dopants into a surface region of p⁻ epi layer 218, using an implant mask. The heavily doped n-type (n⁺) region 222 and heavily doped p-type (p⁺) region 224 may be used to form a low resistance cathode contact and a low resistance anode contact, respectively. In the illustrated example, a shallow trench isolation (STI) region 231 may be formed between p⁺ region 224 and n⁺ region 222, to reduce leakage between p⁺ region 224 and ⁺n region 222 and to avoid edge breakdown between p⁺ region 224 and n⁺ region 222 when a reverse bias is applied. Also, p⁺ region 224, p⁻ epi layer 218, p-type region 216, and n⁺ buried layer 214 may form a vertical layer stack that includes a p⁺/p⁻/p/n⁺ junction structure.

The CMOS circuit may be formed using standard CMOS processes in another region of integrated circuit 200, for example, a region of p⁻ epi layer 218 outside of the junction isolation structure formed by deep n contact 220 and n⁺ buried layer 214. For example, to fabricate PMOS transistor 204, an n-well 240 may be formed in a region of p⁻ epi layer 218 by doping the region of p⁻ epi layer 218 with an n-type dopant, such as As, Sb, or P. P⁺ regions 242 and 244 may then be formed in n-well 240 by p-type doping (e.g., ion implantation or diffusion of boron), and may be used as the source and drain regions of PMOS transistor 204. In some examples, p⁺ regions 242 and 244 (of FIG. 2A-2) and p⁺ regions 224 (of FIG. 2A-1) may be formed in the same process and/or using the same implants, so that regions 224, 242, and 244 are doped with the same p-type dopants (e.g., all regions are doped with boron) at the same (or different) concentrations. A gate 246 of PMOS transistor 204 may then be formed by forming a gate oxide layer (e.g., using chemical vapor deposition (CVD)) and a gate terminal (e.g., including polysilicon or a metal). Similarly, to fabricate NMOS transistor 208, a p-well 250 may be formed in a region of p⁻ epi layer 218 by doping the region of p⁻ epi layer 218 with a p-type dopant, such as boron. N⁺ regions 252 and 254 may then be formed in p-well 250 by n-type doping (e.g., ion implantation or diffusion of an n-type dopant), and may be used as the source and drain regions of NMOS transistor 208. In some examples, n⁺ regions 252 and 254 (of FIG. 2A-2) and n⁺ regions 222 (of FIG. 2A-1) may be formed in the same process and/or using the same implants, so that regions 222, 252, and 254 are doped with the same n-type dopants (e.g., all regions are doped with Sb or As) at the same (or different) concentrations. A gate 256 of NMOS transistor 208 may be formed in the same processes for forming gate 246 of PMOS transistor 204, for example, by forming a gate oxide layer (e.g., using CVD) and a gate terminal (e.g., including polysilicon or a metal) above the gate oxide layer. As described above, resistor 206 may also be formed when fabricating the gate terminals (e.g., polysilicon) of PMOS transistor 204 and NMOS transistor 208. As illustrated, STI regions may be formed between deep n contact 220, n-well 240, and p-well 250 to reduce leakage.

Back end of line (BEOL) processes may then be performed to form electrical interconnects that connect the individual devices. For example, one or more dielectric layers 230 may be deposited on the substrate with APD 202 and the CMOS circuit formed thereon. Vias 234 may be formed in the one or more dielectric layers 230 by, for example, selective etching and metal deposition, to connect metal interconnects 232 formed in one or more patterned metal layers. For example, an anode 236 and a cathode 238 may be formed in or on a dielectric layer 230 for applying the reverse bias to the p⁺/p⁻/p/n⁺ junction of APD 202. Cathode 238 may be electrically coupled to n⁺ region 222 by one or more electrical interconnects (e.g., vias 234 and/or metal interconnects 232). Anode 236 may be electrically coupled to p⁺ region 224 by one or more electrical interconnects (e.g., vias 234 and/or metal interconnects 232). Similarly, one or more vias 234 and one or more metal interconnects 232 may be used to connect a source terminal 248 to the source region (e.g., p⁺ regions 242) of PMOS transistor 204, connect a source terminal 258 to the source region (e.g., n⁺ regions 222) of NMOS transistor 208, connect drain terminals 245 to the drain region (e.g., p⁺ regions 244) of PMOS transistor 204 and drain region (e.g., n⁺ regions 254) of NMOS transistor 208. The connections between APD 202, PMOS transistor 204, resistor 206, and NMOS transistor 208 as shown in FIG. 2B may also be made using one or more vias 234 and one or more metal interconnects 232.

A light transmission window 262 on top of APD 202 may be formed in a light blocking layer 260 (e.g., a metal layer), such that light may pass through light transmission window 262 and detected by the underlying APD 202. Light may be prevented from passing through other regions of light blocking layer 260, for example, to reduce the interference of photo-generated carriers on the performance of other circuits and reduce stray light that may reach APD 202 from other regions. Operations of APD 202 may be similar to operations of APD 101 described above, and thus are not described in detail again with respect to FIG. 2A.

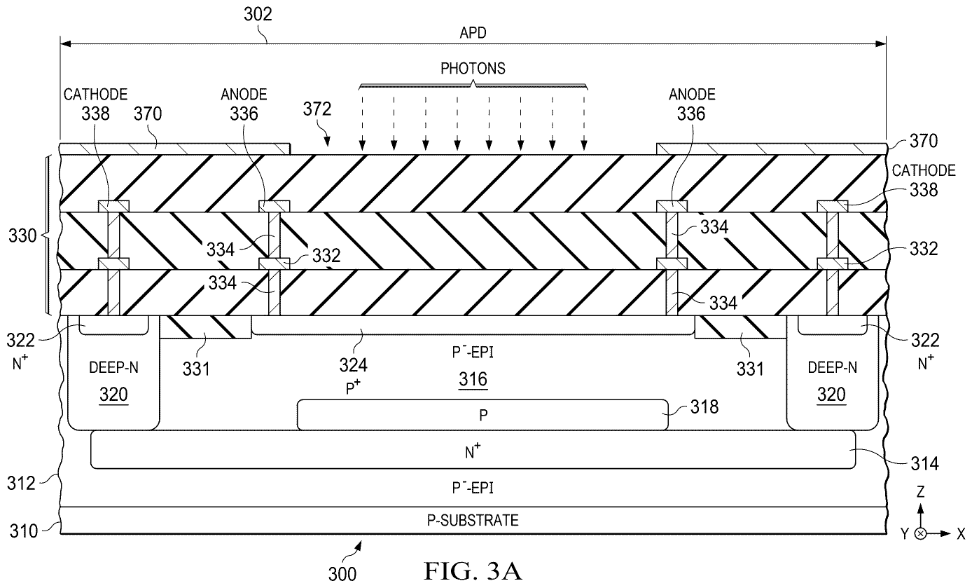

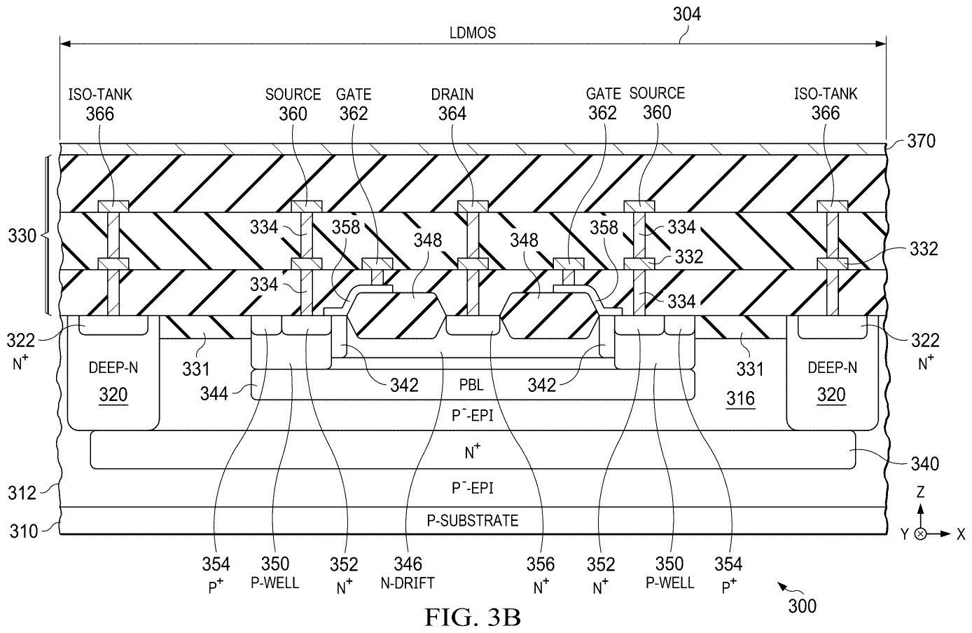

FIG. 3A and FIG. 3B are cross-sectional views of an example of an integrated circuit 300 including an APD 302 and a laterally-diffused metal-oxide-semiconductor (LDMOS) circuit 304. APD 302 may be similar to (or is an example of) APD 202 or 101 described above. LDMOS circuit 304 may include, for example, power devices such as high-voltage transistors or diodes. As illustrated in FIG. 3A and FIG. 3B, APD 302 and the LDMOS circuit may be fabricated in a same die on a same substrate 310. In the illustrated example, substrate 310 may be a p-doped substrate formed by doping the single crystal silicon of a silicon substrate through implantation or diffusion of p-type dopants (e.g., boron). A lightly p-doped epitaxial layer (p⁻ epi layer) 312 may be epitaxially grown on p-doped substrate 310. A first heavily doped n-type buried region (first n⁺ buried region) 314 may be formed in a first region of p⁻ epi layer 312 through the incorporation (e.g., implantation) of n-type dopants, such as As, Sb, or P. In the same process step (or in a subsequent process step), a second heavily doped n-type buried region (second n⁺ buried region) 340 may be formed in a second region of p⁻ epi layer 312 through the incorporation (e.g., implantation) of n-type dopants, such as As, Sb, or P. In one example, after p⁻ epi layer 312 is grown, first n⁺ buried region 314 and second n⁺ buried region 340 may be formed at or near the surface of p⁻ epi layer 312, and another p⁻ epi layer 316 may be grown on top of p⁻ epi layer 312 (and n⁺ buried regions 314 and 340), such that first n⁺ buried region 314 and second n⁺ buried region 340 may be buried under p⁻ epi layer 316. For examples, first n⁺ buried region 314 and second n⁺ buried region 340 may be formed by heavily doping the first region and the second region of p⁻ epi layer 312 at or near the surface of p⁻ epi layer 312 with an n-type dopant via masked implantation or diffusion. The n-type dopant may diffuse deeper into p⁻ epi layer 312 during a thermal annealing process and/or the epitaxial growth of p⁻ epi layer 316, and may partially diffuse into p⁻ epi layer 316 during the epitaxial growth of p⁻ epi layer 316 and/or a subsequent thermal annealing process, thereby forming first n⁺ buried region 314 and second n⁺ buried region 340 in p⁻ epi layer 312 and/or p⁻ epi layer 316.

Deep n contacts 320 (e.g., deep n-wells) may be formed within p⁻ epi layer 316, and may be in contact with edge regions of first n⁺ buried region 314 and edge regions of second n⁺ buried region 340. In some examples as shown in FIG. 3A and FIG. 3B, a deep n contact 320 and first n⁺ buried region 314 may form a junction isolation structure that isolates a first region of p⁻ epi layer 316 above first n⁺ buried region 314, while another deep n contact 320 and second n⁺ buried region 340 may form a junction isolation structure that isolates a second region of p⁻ epi layer 316 above second n⁺ buried region 340. A heavily doped n-type (n⁺) region 322 may be formed within each deep n contact 320, and may be used to form a low resistance contact.

In the first region of p⁻ epi layer 316 above first n⁺ buried region 314, a p-type region 318 may be formed by, for example, implanting p-type dopants before or after the growth of p⁻ epi layer 316, as described in more detail below, so that p-type region 318 and first n⁺ buried region 314 may form a PN junction. A heavily doped p-type (p⁺) region 324 may be formed within the first region of p⁻ epi layer 316 by, for example, implanting a p-type dopants into a surface region of p⁻ epi layer 316, using an implant mask. The heavily doped p-type (p⁺) region 324 may be used to form a low resistance anode contact. In the illustrated example, a shallow trench isolation (STI) region 331 may be formed between p⁺ region 324 and deep n contact 320, to reduce leakage between p⁺ region 324 and deep n contact 320. P⁺ region 324, p⁻ epi layer 316, p-type region 318, and first n⁺ buried region 314 may form a vertical layer stack (e.g., along the z axis) that includes a p⁺/p⁻/p/n⁺ junction structure.

In the second region of p⁻ epi layer 316 above second n⁺ buried region 340, LDMOS circuit 304 may be formed using standard LDMOS processes. LDMOS circuit 304 may include a high-voltage power transistor that can withstand a high voltage between the source and drain when the transistor is turned off (in the off state). The power transistor in the illustrated example may be an n-channel double-diffused MOS field-effect transistor (MOSFET) fabricated using multiple ion implantation and annealing processes. As illustrated, the LDMOS transistor may include a heavily doped n-type (n⁺) drain region 356 surrounded by a relatively lightly doped n-drift region 346, a polysilicon gate 358 on gate oxide 348 formed by local oxidation of silicon (LOCOS), and a heavily doped n-type source region 352 formed in a diffused p-well 350. P-well 350 may be implanted with n-type dopants (e.g., As or Sb) and p-type dopants (e.g., B). The n-type dopants may form source region 352, whereas the p-type dopants may diffuse out laterally to form a p-type diffusion region 342. Also, p-type diffusion region 342 and n-drift region 346 may form a lateral PN junction between the drain and source of the LDMOS transistor. A region of p-well 350 may be heavily doped with a p-type dopant to form a p⁺ region 354. The doping density of n-drift region 346 may be selected such that n-drift region 346 may be depleted when the LDMOS transistor is turned off and a high voltage is applied to the drain, and may also provide low on-state resistance (RDSon) together with the highly doped n⁺ drain region when the LDMOS transistor is turned on (in the on state), thereby achieving high breakdown voltages, low on-state resistance, and good hot carrier injection reliability.

Breakdown in conventional LDMOS transistors may primarily occur due to high electric fields in the region under the gate. The PN junction between p-type diffusion region 342 and n-drift region 346 may be the weakest point for breakdown, and may also define the on-state resistance characteristic of the device. The high electric fields can be significantly lowered by utilizing the reduced surface field (RESURF) effect, which may be used to control the total charge in n-drift region 346 in order to maximize the device breakdown voltage, while achieving low on-state resistance. In the example shown in FIG. 3A and FIG. 3B, the LDMOS transistor may include a relatively lightly doped p-type layer 344 (e.g., p-type buried layer) under n-drift region 346 and connected to the source of the LDMOS transistor through p-well 350 and p⁺ region 354. Therefore, n-drift region 346 and p⁻ epi layer 316 and p-type layer 344 under n-drift region 346 may form a vertical PN junction between the drain and source of the LDMOS transistor. When the LDMOS transistor is turned off and a high voltage is applied to the drain, the n-drift region 346 may be depleted both in the horizontal direction due to the reversely biased PN junction between p-type diffusion region 342 and n-drift region 346, and in the vertical direction due to the reversely biased PN junction between n-drift region 346 and p-type layer 344, thereby enhancing the growth of the depletion layer at the surface (e.g., in n-drift region 346). Device parameters such as doping density, layer thickness, and structural geometry may be selected such that, when the drain voltage is high, the vertical depletion may extend to the surface of the silicon to completely deplete n-drift region 346. Once this occurs, n-drift region 346 under the gate edge may effectively be isolated from n⁺ drain region 356, and the electric field under the gate may remain approximately constant as the drain voltage is increased. Therefore, the lateral (surface) electric field of the PN junction between p-type diffusion region 342 and n-drift region 346 may be reduced, and the LDMOS transistor may break down at a voltage that is mainly determined by the PN junction between n-drift region 346 and p-type layer 344, which can be made high. Due to the RESURF effect, n-drift region 346 can be relatively highly doped to reduce on-state resistance, without reducing the breakdown voltage.

Back end of line processes may be performed to form electrical interconnects that connect the individual devices formed on the substrate. For example, one or more dielectric layers 330 may be deposited on the substrate with APD 302 and LDMOS circuit 304 formed thereon. Vias 334 may be formed in the one or more dielectric layers 330 by, for example, selective etching and metal deposition, to connect metal interconnects 332 formed in one or more patterned metal layers. For example, an anode 336 and a cathode 338 may be formed in or on a dielectric layer 330 to apply the reverse bias to the p⁺/p⁻/p/n⁺ junction of APD 302. Cathode 338 may be electrically coupled to n⁺ region 322 by one or more electrical interconnects (e.g., vias 334 and/or metal interconnects 332). Anode 336 may be electrically coupled to p⁺ region 324 by one or more electrical interconnects (e.g., vias 334 and/or metal interconnects 332). Similarly, one or more vias 334 and/or one or more metal interconnects 332 may be used to connect a source terminal 360 to the source region 352 of the LDMOS transistor, connect a gate terminal 362 to a polysilicon gate 358 of the LDMOS transistor, connect a drain terminal 364 to the drain region (e.g., n⁺ regions 356) of the LDMOS transistor, and connect an isolation terminal 366 to n⁺ region 322 and deep n contacts 320 (e.g., deep n-wells) that surround and isolate the LDMOS transistor. Other connections between different devices on a die or substrate may also be made using one or more vias 334 and/or one or more metal interconnects 332.

A light transmission window 372 on top of APD 302 may be formed in a light blocking layer 370 (e.g., a metal layer), such that light may pass through light transmission window 372 and detected by the underlying APD 302. Light may be prevented from passing through other regions of light blocking layer 370, for example, to reduce the interference of photo-generated charge carriers on the performance of other circuits and reduce stray light that may reach APD 302 from other regions. Operations of APD 302 may be similar to operations of APD 101 or 202 described above, and thus are not described again with respect to FIG. 3A and FIG. 3B.

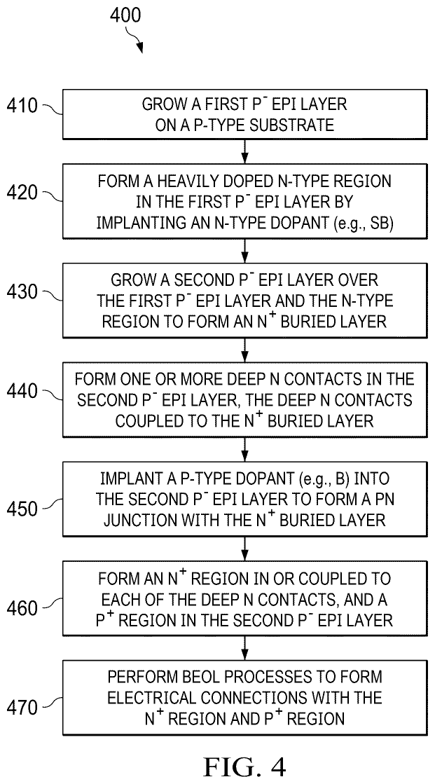

FIG. 4 is a flowchart 400 illustrating an example of a process of fabricating an APD. It is noted that the operations illustrated in FIG. 4 provide particular processes for fabricating an APD. Other sequences of operations can also be performed according to alternative examples. For example, alternative examples may perform the operations in a different order. Moreover, the individual operations illustrated in FIG. 4 can include multiple sub-operations that can be performed in various sequences as appropriate for the individual operation. Furthermore, some operations can be added or removed depending on the particular examples. In some examples, two or more operations may be performed in parallel. One of ordinary skill in the art would recognize many variations, modifications, and alternatives.

Operations in block 410 may include growing a first lightly doped p-type epitaxial layer (p⁻ epi layer) on a p-type doped substrate. For example, p-type dopants (e.g., boron) may be incorporated into undoped single crystal silicon of a silicon substrate by implantation or diffusion to form the p-type doped substrate. The first p⁻ epi layer may then be grown on the p-type doped substrate. The epitaxy process may use, for example, silane, dichlorosilane, or other silicon-containing reagents. The epitaxy process may also use a boron containing reagent such as diborane to provide p-type dopants in the first p⁻ epi layer. Alternatively, p-type dopants such as boron may be implanted into the first p⁻ epi layer after the epitaxy process is completed. In some examples, the first p⁻ epi layer may have a resistivity between about 1 ohm-cm to about 100 ohm-cm.

Operations in block 420 may include forming a heavily doped n-type (n⁺) region in the first p⁻ epi layer by implanting an n-type dopant (e.g., Sb). For example, the n⁺ region may be formed in a surface region of the first p⁻ epi layer through the incorporation (e.g., implantation or diffusion) of n-type dopants, such as As, Sb, or P. In subsequent processes, the n-type dopants may diffuse farther into the first p⁻ epi layer during a thermal annealing process and/or the epitaxial growth of a second p⁻ epi layer over the first p⁻ epi layer, and may also diffuse into the second p⁻ epi layer during the epitaxial growth of the second p⁻ epi layer and/or a subsequent thermal annealing process, thereby forming the n⁺ buried layer between the first p⁻ epi layer and the second p⁻ epi layer.

In some examples, to form the n⁺ region in the first p⁻ epi layer, a layer of pad oxide may be formed over the first p⁻ epi layer, and an implant mask may be formed over the layer of pad oxide to expose an area of the first p⁻ epi layer. The implant mask may include, for example, photoresist formed by a photolithographic process, or may include hard mask material such as silicon dioxide formed by a thermal oxidation or a plasma enhanced chemical vapor (PECVD) process. N-type dopants may then be implanted through the area exposed by the implant mask into the first p⁻ epi layer to form an implanted n⁺ layer. In one example, the n-type dopants may include at least 50 percent arsenic and/or antimony. For example, the n-type dopants may be substantially all antimony. The n-type dopants may be implanted, for example, at a dose greater than about 5×10¹⁴ cm⁻², such as between about 1×10¹⁵ cm⁻² and about 5×10¹⁵ cm⁻². Antimony in the n-type dopants may be implanted at energies, for example, less than about 50 keV. Arsenic in the n-type dopants may be implanted at energies, for example, less than about 40 keV. In some examples, phosphorus may be implanted through the area exposed by the implant mask into the first p⁻ epi layer to form an additional n-type layer below the implanted n⁺ layer. The phosphorus may be implanted, for example, at a dose between about 1×10¹³ cm⁻² and about 1×10¹⁴ cm⁻² and at an energy above 100 keV. In some examples, after implanting the n-type dopants into the first p⁻ epi layer, a first thermal drive process may be performed to heat the first p⁻ epi layer to a temperature between about 1150° C. and about 1225° C. for at least about 30 minutes. The first thermal drive process may be performed, for example, in a furnace with an oxidizing ambient that may increase the thickness of the layer of pad oxide. The first thermal drive process may cause the implanted n-type dopants to diffuse deeper into the first p⁻ epi layer. The phosphorus may diffuse farther into the first p⁻ epi layer than arsenic and antimony due to the higher diffusion constant of phosphorus. The layer of pad oxide may be removed subsequently, for example, by a wet etch using a dilute aqueous solution of buffered hydrofluoric acid.

In block 430, a second p⁻ epi layer may be grown over the first p⁻ epi layer and the n⁺ region (e.g., the implanted n⁺ layer). The epitaxy process may use silane, dichlorosilane, or other silicon-containing reagents. The epitaxy process may also use a boron-containing reagent such as diborane to provide p-type dopants in the second p⁻ epi layer. Alternatively, p-type dopants such as boron may be implanted into the second p⁻ epi layer after the epitaxy process is completed. During the epitaxial growth of the second p⁻ epi layer, the n-type dopants in the implanted n⁺ layer in the first p⁻ epi layer may diffuse farther into the first p⁻ epi layer and may also diffuse into the second p⁻ epi layer, to form an n-type buried layer that straddles the boundary between the first p⁻ epi layer and the second p⁻ epi layer.

In some examples, after the growth of the second p⁻ epi layer, a second thermal drive process may be performed to heat the substrate to a temperature between about 1125° C. and about 1200° C. for at least about 120 minutes. The second thermal drive process may also be performed in a furnace with a slightly oxidizing ambient. When the second thermal drive is completed, an n⁺ buried layer may extend at least about a micron into the first p⁻ epi layer and at least about a micron into the second p⁻ epi layer. In some examples, a top surface of the n⁺ buried layer may be at least about 5 microns (e.g., about 8 microns to 12 microns) below a top surface of the second p⁻ epi layer. An average doping concentration in the n⁺ buried layer may be greater than about 5×10¹⁸ cm⁻³, such as about 1×10¹⁹ cm⁻³. At least 50 percent of the n-type dopants in the n⁺ buried layer may be arsenic and/or antimony. In some examples where phosphorus may be implanted into the first p⁻ epi layer to form the additional n-type layer below the implanted n⁺ layer, the lightly-doped additional n-type layer may extend at least about 2 microns below the implanted n⁺ layer. An average doping in the lightly-doped additional n-type layer may be about 1×10¹⁶ cm⁻³ to about 1×10¹⁷ cm⁻³, where at least about 90 percent of the n-type dopants in the lightly-doped additional n-type layer may be phosphorus. The structure of the n⁺ buried layer with the lightly-doped layer may advantageously prevent breakdown of a PN junction between the n⁺ buried layer and the first p⁻ epi layer, and may advantageously provide a desired low level of leakage current. The n⁺ buried layer may also advantageously provide a low sheet resistance so as to maintain a uniform bias for components in the second p⁻ epi layer above the n⁺ buried layer. Various examples of operations of blocks 420 and 430 are described in U.S. Pat. No. 9,385,187, titled “High Breakdown N-type Buried Layer,” the entirety of which is hereby incorporated by reference.

Operations in block 440 may include forming one or more deep n contacts (sinkers) in the second p⁻ epi layer, where the deep n contacts may be coupled to the n⁺ buried layer. In some examples, the one or more deep n contacts may be formed by a deep-n implant process and a long anneal process. In some examples, the deep n contacts may be in contact with edge regions of the n⁺ buried layer, and thus may, in combination with the n⁺ buried layer, form a junction isolation structure that isolates the p-type multiplication layer and the absorption region (e.g., a region of the second p⁻ epi layer above the p-type multiplication layer) of the APD from other circuits fabricated on the substrate, so that the APD may have lower noise and better performance. In one example, the deep n contacts may include deep n-wells formed by implanting dopants in one or more doses followed by activation anneal. In some examples, the deep n contacts may be formed by forming a deep trench down to the n⁺ buried layer, implanting dopants (e.g., at a slanted angle) into the second p⁻ epi layer along sidewalls of the deep trench, and subsequently filling the deep trench with an electrically conductive material such as polysilicon (e.g., by depositing a conformal layer of polysilicon and subsequently removing the polysilicon on the top surface of the second p⁻ epi layer using, for example, a chemical mechanical polishing (CMP) process). Various examples of operations in block 440 are described in detail in U.S. Pat. No. 9,431,209, titled “Deep Trench with Self-Aligned Sinker,” the entirety of which is hereby incorporated by reference.

Operations in block 450 may include implanting a p-type dopant (e.g., B) into the second p⁻ epi layer to form a p-type multiplication layer that may form a PN junction with the n⁺ buried layer. Implanting the p-type dopant into the second p⁻ epi layer may be performed by, for example, forming an implant mask on the second p⁻ epi layer to expose a region of the second p⁻ epi layer, and implanting the p-type dopant into the exposed region of the second p⁻ epi layer using high-energy implants so that the p-type dopant may penetrate deep into the second p⁻ epi layer. In one example where the second p⁻ epi layer has a thickness about 5 μm, the p-type multiplication layer may be formed by implanting boron at an energy between about 2.6 MeV and 2.8 MeV (e.g., about 2.7 MeV), and a dose between about 2.0×10¹² cm⁻² and 3.0×10¹² cm⁻² (e.g., about 2.5×10¹² cm⁻²), which may yield a breakdown voltage between about 30 V and 50 V. In some examples, an annealing process may be performed after implanting the p-type dopant (e.g., B) into the second p⁻ epi layer, such that some p-type dopants may diffuse towards the n⁺ buried layer and/or some n-type dopants in the n⁺ buried layer may diffuse further into the second p⁻ epi layer, thereby forming the PN junction between the n⁺ buried layer and the p-type multiplication layer.

Operations in block 460 may include forming an n⁺ region in or coupled to each of the one or more deep n contacts, and forming a p⁺ region in the second p⁻ epi layer above the p-type multiplication layer. For example, a region of each of the one or more deep n-wells may be implanted with an n-type dopant (e.g., As, Sb, or P) to form an n⁺ region that may be used as a low-resistance contact region for the cathode of the APD. The p⁺ region above the p-type multiplication layer may be formed in the second p⁻ epi layer by, for example, implanting a p-type dopants into a surface region of the second p⁻ epi layer using an implant mask, and may be used as a low-resistance contact region for the anode of the APD. In some examples, a shallow trench isolation (STI) region may be formed between the p⁺ region and the n⁺ region to reduce leakage. The n⁺ buried layer, the p-type multiplication layer, the second p⁻ epi layer above the p-type multiplication layer, and the p⁺ region may form a p⁺/p⁻/p/n⁺ junction structure of an APD.

In block 470, back end of line processes may be performed to form electrical connections with the n⁺ region and p⁺ region. For example, one or more dielectric layers (e.g., oxide layers) may be deposited on the semiconductor layer stack with the APD formed therein. Vias may be formed in the one or more dielectric layers by, for example, selective etching and metal deposition. One or more metal layers (e.g., copper or aluminum layers) may be deposited and patterned on the one or more dielectric layers to form metal interconnects. The metal interconnects may include at least an anode and a cathode for the APD, and may be coupled to the n⁺ region and p⁺ region though one or more metal interconnects and/or one or more vias to apply a reverse bias to the APD. As described above, the metal interconnects and vias may also be used to connect the APD to other devices fabricated on the same substrates, such as CMOS and/or LDMOS circuits.

Examples of techniques for reduce threading dislocations caused by high energy and/or high dose ion implant may be used during the fabrication of the APD, as described in, for example, U.S. Pat. No. 7,466,009, titled “Method for Reducing Dislocation Threading Using a Suppression Implant,” the entirety of which is hereby incorporated by reference.

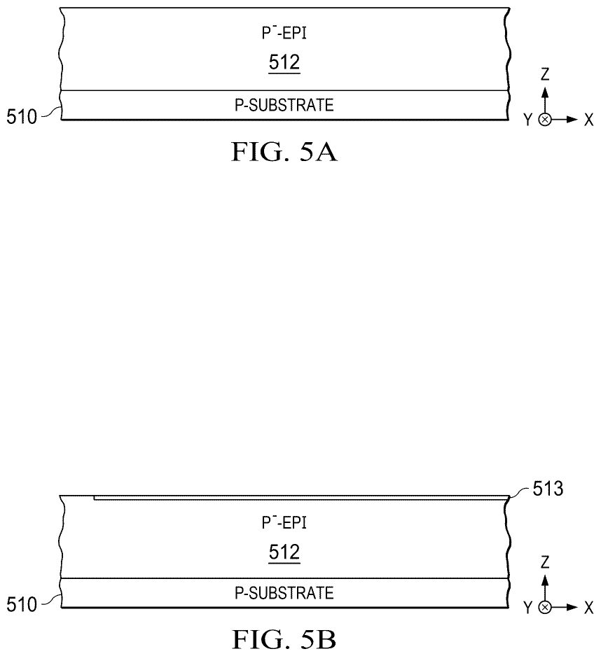

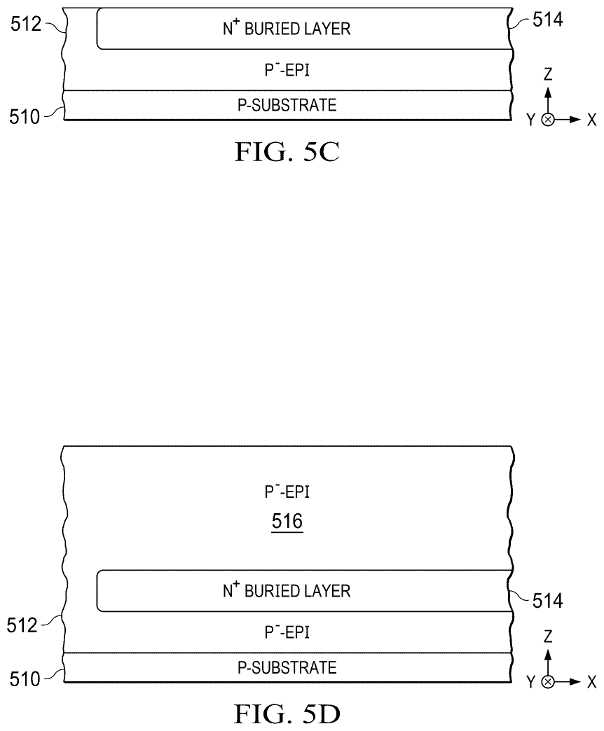

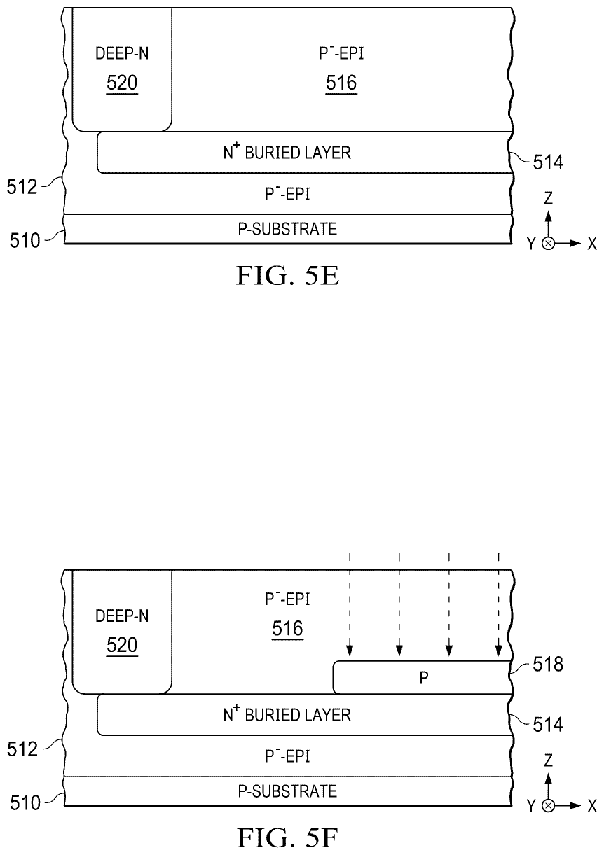

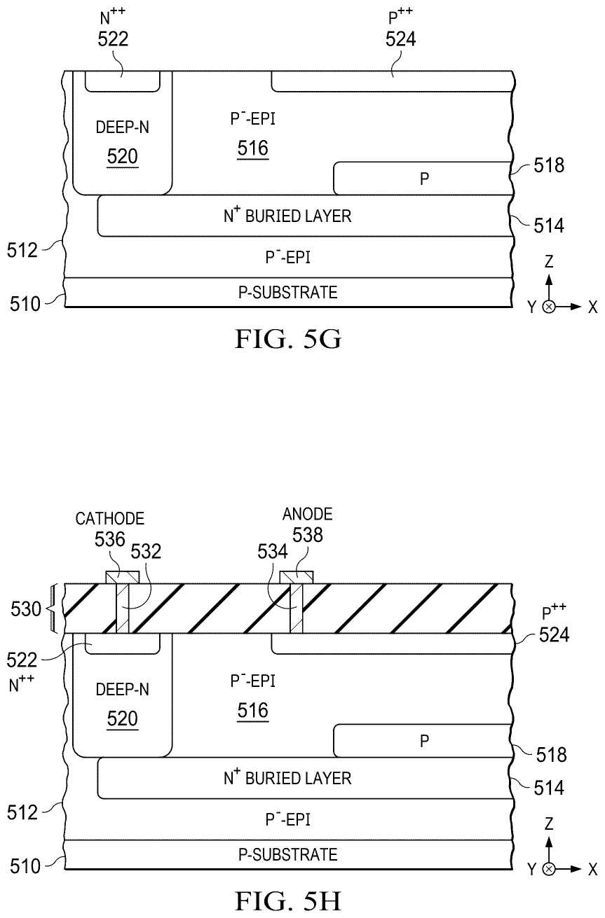

FIGS. 5A-5H illustrate cross-sections of a semiconductor device in the process of fabricating an APD of FIG. 4. FIG. 5A illustrates an example of a semiconductor wafer or die including a p-type substrate 510 and a lightly doped p-type epitaxial (p⁻ epi) layer 512 grown on p-type substrate 510. The semiconductor wafer or die shown in FIG. 5A may be fabricated using operations described above with respect to block 410 of FIG. 4. P-type substrate 510 and p⁻ epi layer 512 may include a same base semiconductor material, such as silicon. In one example, p-type substrate 510 may be a single crystalline silicon wafer doped with boron, and p⁻ epi layer 512 may be a silicon epitaxial layer with boron incorporated during or after the epitaxial growth.

FIG. 5B illustrates an example of a heavily doped n-type (n⁺) region 513 formed at a surface region of p⁻ epi layer 512. N⁺ region 513 may be formed using a mask and operations described above with respect to, for example, block 420 of FIG. 4. The n-type dopants in n⁺ region 513 may include, for example, As, Sb, P, or a combination thereof, and may be incorporated into p⁻ epi layer 512 by diffusion or one or more ion implanting processes. For example, as described above, n⁺ region 513 may be formed by implanting arsenic and/or antimony into p⁻ epi layer 512, and optionally, implanting phosphorus deeper into p⁻ epi layer 512.

FIG. 5C shows that the semiconductor wafer or die may optionally be annealed at an elevated temperature (e.g., about 1150° C. to about 1225° C.) for a time period (e.g., at least about 30 minutes) as described above with respect to block 420 of FIG. 4, such that the implanted n-type dopants in n⁺ region 513 may diffuse deeper into p⁻ epi layer 512 to form an n⁺ buried layer 514.

In FIG. 5D, a p⁻ epi layer 516 may be grown on p⁻ epi layer 512 and n⁺ buried layer 514 as described above with respect to, for example, block 430 of FIG. 4. P⁻ epi layer 516 may include silicon and p-type impurities (e.g., boron) incorporated during or after the epitaxial growth of p⁻ epi layer 516. Therefore, n⁺ buried layer 514 may be buried between p⁻ epi layer 512 and p⁻ epi layer 516. During the epitaxial growth, the n-type dopants in n⁺ buried layer 514 may diffuse deeper into p⁻ epi layer 512 and may also diffuse into p⁻ epi layer 516, due to the elevated temperature during the epitaxial growth. In some examples, the semiconductor wafer or die may optionally be annealed at an elevated temperature (e.g., between about 1125° C. and about 1200° C.) for a time period (e.g., at least about 120 minutes), during which the n-type dopants in n⁺ buried layer 514 may diffuse deeper into p⁻ epi layer 512 and may also diffuse into p⁻ epi layer 516.

In FIG. 5E, at least one deep n contact 520 may be formed in p⁻ epi layer 516 and in contact with an edge region of n⁺ buried layer 514. Deep n contact 520 may be formed using, for example, operations described above with respect to block 440 of FIG. 4. Deep n contact 520 may include, for example, a deep n-well formed by implant and anneal processes, or a deep trench with a self-aligned sinker along sidewalls of the deep trench and an electrically conductive material (e.g., polysilicon) filling the deep trench as described above.

FIG. 5F shows that p-type dopants such as boron may be implanted into a region of p⁻ epi layer 516 from the top surface of p⁻ epi layer 516, for example, using an implant mask (not shown in FIG. 5F), as described above with respect to, for example, block 450 of FIG. 4. The energy and dose of the p-type dopants may be selected such that the p-type dopants may penetrate deep into a region of p⁻ epi layer 516 to form a p-type multiplication layer 518 that is close to n⁺ buried layer 514, thereby forming a PN junction between p-type multiplication layer 518 and n⁺ buried layer 514. In some examples, the semiconductor wafer or die may be annealed so that some p-type dopants in p-type multiplication layer 518 may diffuse towards n⁺ buried layer 514 and some n-type dopants in n⁺ buried layer 514 may diffuse further into p⁻ epi layer 516 to form the PN junction between p-type multiplication layer 518 and n⁺ buried layer 514.

FIG. 5G shows an n⁺⁺ (or n⁺) region 522 formed in deep n contact 520, and a p⁺⁺ (or p⁺ region 524 formed in a region of p⁻ epi layer 516 above p-type multiplication layer 518, using operations described above with respect to, for example, block 460 of FIG. 4. N⁺⁺ region 522 may be formed by implantation or diffusion of an n-type dopant such as P, Sb, or As, and may be used as a low-resistance cathode contact. P⁺⁺ (or p⁺) region 524 may be formed by implantation or diffusion of a p-type dopant such as boron, and may be used as a low-resistance anode contact. P⁺⁺ region 524, a region of p⁻ epi 516 below p⁺⁺ region 524, p-type multiplication layer 518, and n⁺ buried layer 514 may form a p⁺/p⁻/p/n⁺ junction structure of an APD.

FIG. 5H shows that electrical interconnects may be formed in or on one or more dielectric layers 530 (e.g., silicon oxide layers) using BEOL processes described above with respect to, for example, block 470 of FIG. 4. For example, a cathode 536 may be electrically coupled to n⁺⁺ region 522 through at least one via 532 formed in a dielectric layer 530, whereas an anode 538 may be electrically coupled to an edge region of p⁺⁺ region 524 through at least one via 534 formed in dielectric layer 530. As described above with respect to, for example, FIGS. 2 and 3, CMOS circuits, BiCMOS circuit, and/or LDMOS circuits may also be fabricated on the semiconductor wafer or die using similar processes.

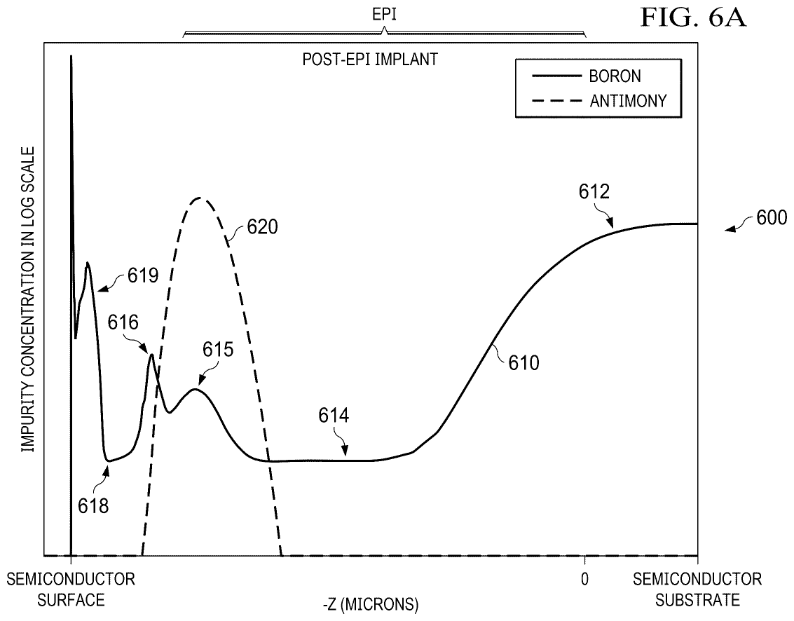

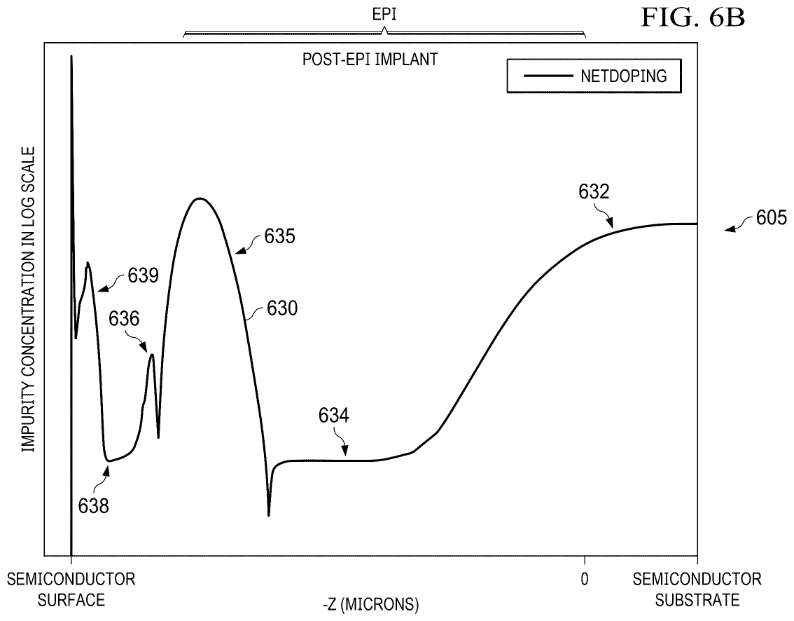

FIG. 6A is a diagram 600 illustrating n-dopant and p-dopant concentration profiles of an example of an APD (e.g., shown in FIG. 5G or 5H) where the multiplication layer (e.g., p-type multiplication layer 518) of the APD may be formed by implanting dopants into an epitaxial layer (e.g., p⁻ epi layer 516) after the growth of the epitaxial layer. The horizontal axis of the diagram corresponds to locations within p-type substrate 510 in the −z direction (e.g., the surface normal direction of p-type substrate 510) shown in FIG. 5H, where a position with a value 0 on the horizontal axis may correspond to the interface between p-type substrate 510 and p⁻ epi layer 512. The vertical axis corresponds to the impurity (dopant) concentration (in log scale) in unit volume (e.g., cm⁻³). An impurity concentration profile 610 shows the p-dopant (e.g., boron) concentration in the semiconductor layer stack of the APD, while an impurity concentration profile 620 shows the n-dopant (e.g., Sb) concentration in the semiconductor layer stack of the APD.

A region 612 of impurity concentration profile 610 shows the concentration of boron in p-type substrate 510. A region 614 of impurity concentration profile 610 shows the concentration of boron in p⁻ epi layer 512. A region 615 of impurity concentration profile 610 shows the concentration of boron in n⁺ buried layer 514 (e.g., due to a blanket p-implant for the entire wafer). A region 616 of impurity concentration profile 610 shows the concentration of boron in p-type multiplication layer 518. A region 618 of impurity concentration profile 610 shows the concentration of boron in p⁻ epi layer 516. A region 619 of impurity concentration profile 610 shows the concentration of boron in p⁺⁺ region 524. Impurity concentration profile 610 shows that the peak concentration of boron in n⁺ buried layer 514 may be lower than the peak concentration of boron in p-type multiplication layer 518. Impurity concentration profile 620 shows that the n-type dopants (e.g., Sb) are mainly in n⁺ buried layer 514, and may have a concentration higher than the p-type dopant in n⁺ buried layer 514. Impurity concentration profile 620 also shows that the n-type dopant may diffuse into p⁻ epi layer 512 and p⁻ epi layer 516 (or p-type multiplication layer 518), but may have a lower concentration than the p-type dopant in p⁻ epi layer 512 and p⁻ epi layer 516 (or p-type multiplication layer 518), such that p⁻ epi layer 512 and p⁻ epi layer 516 (and p-type multiplication layer 518) may be relatively lightly p-doped.

FIG. 6B is a diagram 605 illustrating an impurity concentration profile 630 of the net dopants in the example of the APD of FIG. 6A. The horizontal axis of the diagram corresponds to the −z direction shown in FIG. 5G or 5H, where a position with a value 0 on the horizontal axis may correspond to the interface between p-type substrate 510 and p⁻ epi layer 512. The vertical axis corresponds to the net impurity concentration (in log scale) in unit volume (e.g., cm⁻³). A region 632 of impurity concentration profile 630 shows the concentration of the p-type dopant (e.g., B) in p-type substrate 510. A region 634 of impurity concentration profile 630 shows the net concentration of the p-type dopant (e.g., B) in p⁻ epi layer 512. A region 635 of impurity concentration profile 630 shows the net concentration of the n-type dopant (e.g., As, Sb, or P) in n⁺ buried layer 514. A region 636 of impurity concentration profile 630 shows the net concentration of the p-type dopant (e.g., B) in p-type multiplication layer 518. A region 638 of impurity concentration profile 630 shows the concentration of the p-type dopant (e.g., B) in p⁻ epi layer 516. A region 639 of impurity concentration profile 630 shows the concentration of the p-type dopant (e.g., B) in p⁺⁺ region 524.

Forming p-type multiplication layer 518 using processes described above with respect to block 450 or FIG. 5F may use high-energy implants that may be difficult or expensive to achieve, and may cause damages to the crystalline structure of the semiconductor layer and thus may degrade the performance and/or reliability of the APD devices. According to some examples, after forming a heavily doped n⁺ buried layer that includes an n-type dopant (e.g., antimony), a p-type dopant (e.g., boron) that has a higher diffusion constant than the n-type dopant may be implanted into a region of the n⁺ buried layer. An intrinsic or lightly p-doped epitaxial layer may be grown over the n⁺ buried layer. During the epitaxial growth of the intrinsic or lightly p-doped epitaxial layer and/or subsequent annealing processes, the p-type dopant having the higher diffusion constant may diffuse from the n⁺ buried layer into the intrinsic or lightly doped epitaxial layer at a rate faster than the n-type dopant, and thus may have a higher concentration than the n-type dopant in a region of the intrinsic or lightly p-doped epitaxial layer adjacent to the n⁺ buried layer. As such, the region of the intrinsic or lightly p-doped epitaxial layer adjacent to the n⁺ buried layer may have a higher net p-dopant concentration than the rest of the intrinsic or lightly p-doped epitaxial layer, and thus a p-doped region adjacent to the n⁺ buried layer may be formed to function as the multiplication layer. Therefore, the APD can be fabricated without performing high-energy p-dopant implanting. By selecting the proper dose and energy for implanting the p-type dopant, a pn⁺ junction with a target impurity concentration profile and layer thicknesses may be formed to achieve the target APD performance. In another example, the multiplication layer may be formed by high-energy implanting from the top of the intrinsic or lightly doped epitaxial layer, and various techniques for mitigating the damages to the crystalline structure of the semiconductor layer caused by the high-energy implanting may be used to improve the performance and/or reliability of the APD devices.

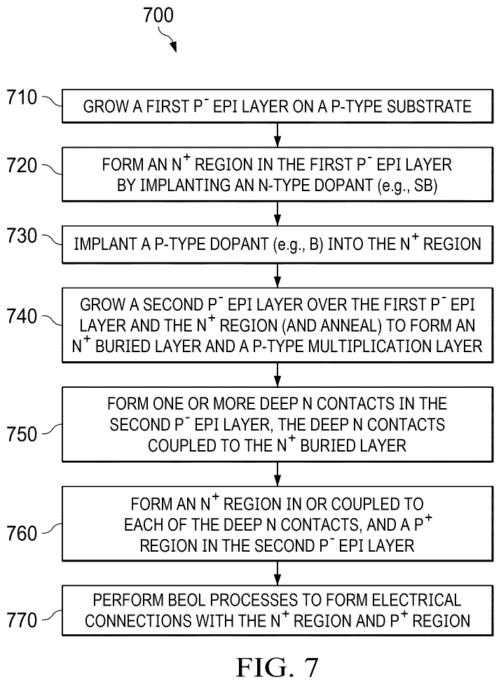

FIG. 7 is a flowchart 700 illustrating an example of a process of fabricating an APD. It is noted that the operations illustrated in FIG. 7 provide particular processes for fabricating APDs. Other sequences of operations can also be performed according to alternative examples. For example, alternative examples may perform the operations in a different order. Moreover, the individual operations illustrated in FIG. 7 can include multiple sub-operations that can be performed in various sequences as appropriate for the individual operation. Furthermore, some operations can be added or removed depending on the particular examples. In some examples, two or more operations may be performed in parallel. One of ordinary skill in the art would recognize many variations, modifications, and alternatives.

Operations in block 710 may be similar to operations in block 410 of FIG. 4 and may include growing a first lightly doped p-type epitaxial layer (p⁻ epi layer) on a p-type doped substrate. For example, p-type dopants (e.g., boron) may be incorporated into undoped single crystal silicon of a silicon substrate by implantation or diffusion to form the p-type doped substrate. The first p⁻ epi layer may then be grown on the p-type doped substrate. The epitaxy process may use, for example, silane, dichlorosilane, or other silicon-containing reagents. The epitaxy process may also use a boron containing reagent such as diborane to incorporate p-type dopants in the first p⁻ epi layer. Alternatively, p-type dopants such as boron may be implanted into the first p⁻ epi layer after the epitaxy process is completed. In some examples, the first p⁻ epi layer may have a resistivity of about 1 ohm-cm to about 100 ohm-cm.

Operations in block 720 may be similar to operations in block 420 of FIG. 4 and may include forming a heavily doped n-type (n⁺) region in the first p⁻ epi layer by implanting or diffusing an n-type dopant. For example, the n⁺ region may be formed in a surface region of the first p⁻ epi layer through the incorporation (e.g., implantation or diffusion) of n-type dopants, such as As, Sb, or P. As described above with respect to block 420 of FIG. 4, in some examples, a layer of pad oxide may be formed over the first p⁻ epi layer, and an implant mask may be formed over the layer of pad oxide to expose an area of the first p⁻ epi layer. N-type dopants may then be implanted through the area exposed by the implant mask into the first p⁻ epi layer to form an implanted n⁺ layer. In one example, the n-type dopants may include at least 50 percent arsenic and/or antimony. For example, the n-type dopants may be substantially all antimony. The n-type dopants may be implanted, for example, at a dose greater than about 5×10¹⁴ cm⁻², such as about 1×10¹⁵ cm⁻² to about 5×10¹⁵ cm⁻². Antimony in the n-type dopants may be implanted, for example, at energies less than about 50 keV. Arsenic in the n-type dopants may be implanted, for example, at energies less than about 40 keV. In some examples, an additional implant process may be performed to implant phosphorus into the first p⁻ epi layer to form an additional n-type layer below the implanted n⁺ layer formed by implanting antimony or arsenic. The phosphorus may be implanted, for example, at a dose of about 1×10¹³ cm⁻² to about 1×10¹⁴ cm⁻² and at an energy above 100 keV. In some examples, after implanting the n-type dopants into the first p⁻ epi layer, an annealing process may be performed to heat the first p⁻ epi layer to a temperature of about 1150° C. to about 1225° C. for at least about 30 minutes. The first thermal drive process may be performed, for example, in a furnace with an oxidizing ambient. The first thermal drive process may cause the implanted n-type dopants to diffuse deeper into the first p⁻ epi layer to form an n⁺ buried layer. Phosphorus (if implanted) may diffuse farther into the first p⁻ epi layer than arsenic and/or antimony due to the higher diffusion constant of phosphorus. The layer of pad oxide may be removed subsequently, for example, by wet-etching using a dilute aqueous solution of buffered hydrofluoric acid.

In block 730, a p-type dopant (e.g., B) may be implanted into a portion of the n⁺ region formed by the operations in block 720. Ther p-type dopant may have a higher diffusion constant than the n-type dopants in the n⁺ region. Implanting the p-type dopant into the portion of the n⁺ region may be performed by, for example, forming an implant mask on the first p⁻ epi layer to expose the portion of the n⁺ region, and implanting the p-type dopant into the exposed portion of the n⁺ region, for example, at a dose between about 3.4×10¹³ cm⁻² and about 6.1×10¹³ cm⁻² (e.g., about 4.3×10¹³ cm⁻²) and an energy between about 70 keV and 110 keV (e.g., about 95 keV), in order to fabricate an APD with a breakdown voltage between about 30 V and about 50 V. The dose of the p-type dopant may be adjusted to tune the target reverse bias voltage for avalanche multiplication. For example, a lower reverse bias voltage for avalanche multiplication may be achieved using a higher dose of the p-type dopant, while a higher reverse bias voltage for avalanche multiplication may be achieved using a lower dose of the p-type dopant.

In block 740, a second p⁻ epi layer may be grown over the first p⁻ epi layer and the n⁺ region. In some examples, before growing the second p⁻ epi layer, an etch process may be performed to clean the surface of the first p⁻ epi layer and the n⁺ region. The epitaxy process may use silane, dichlorosilane, or other silicon-containing reagents. The epitaxy process may also use a boron-containing reagent such as diborane to incorporate p-type dopants in the second p⁻ epi layer. Alternatively, p-type dopants such as boron may be implanted into the second p⁻ epi layer after the epitaxy process is completed. During the epitaxial growth of the second p⁻ epi layer, the n-type dopants in the n⁺ region in the first p⁻ epi layer may diffuse farther into the first p⁻ epi layer and may also diffuse into the second p⁻ epi layer, to form an n⁺ buried layer that straddles the boundary between the first p⁻ epi layer and the second p⁻ epi layer. In some examples, the thickness of the second p⁻ epi layer may be greater than a few microns, such as about 5 microns or thicker.

In some examples, an annealing process may be performed after the growth of the second p⁻ epi layer, such that the n-type dopants and p-type dopants in the n⁺ region may diffuse further into the first p⁻ epi layer and the second p⁻ epi layer. For example, the annealing process may be performed in a furnace with a slightly oxidizing ambient and at a temperature between about 1100° C. to about 1200° C. for 30 minutes or longer. The n-type dopants in the n⁺ region may diffuse into both the first p⁻ epi layer and the second p⁻ epi layer to form the n⁺ buried layer. Since the p-type dopants (e.g., boron) may have a higher diffusion constant than the n-type dopants (e.g., As or Sb), more p-type dopants may diffuse deeper into the second p⁻ epi layer to form a net p-type region above the n⁺ buried layer. When the annealing process is completed, the n⁺ buried layer may extend at least about a micron into the first p⁻ epi layer and at least about a micron into the second p⁻ epi layer. In some examples, a top surface of the n⁺ buried layer may be at least about 5 microns (e.g., about 8 microns to 12 microns) below a top surface of the second p⁻ epi layer. A peak doping concentration in the n⁺ buried layer may be greater than about 5×10¹⁸ cm⁻³, such as close to about 1×10¹⁹ cm⁻³. A peak doping concentration in the p-type region may be, for example, greater than about 1×10¹⁶ cm⁻³. The p-type region in the second p⁻ epi layer may form a PN junction with the n⁺ buried layer, and may be used as the p-type multiplication layer of the APD.

Operations in block 750 may be similar to operations in block 450, and may include forming one or more deep n contacts (sinkers) in the second p⁻ epi layer, where the deep n contacts may be coupled to the n⁺ buried layer. In some examples, the deep n contacts may be in contact with edge regions of the n⁺ buried layer, and thus may, in combination with the n⁺ buried layer, form a junction isolation structure that isolates the p-type multiplication layer and the absorption region of the APD from other circuits fabricated on the substrate, so that the APD may have lower noise and better performance. In one example, the deep n contacts may include deep n-wells formed by implanting dopants in one or more doses followed by activation anneal. In some examples, the deep n contacts may be formed by forming a deep trench down to the n⁺ buried layer, implanting dopants (e.g., at a slanted angle) into the second p⁻ epi layer along sidewalls of the deep trench, and subsequently filling the deep trench with an electrically conductive material such as polysilicon (e.g., by depositing a conformal layer of polysilicon and subsequently removing the polysilicon on the top surface of the second p⁻ epi layer using, for example, a CMP process), as described above with respect to block 450 of FIG. 4.

Operations in block 760 may include forming an n⁺ region in or coupled to each of the one or more deep n contacts, and forming a p⁺ region in the second p⁻ epi layer above the p-type multiplication layer. For example, a region of each of the one or more deep n-wells may be implanted with an n-type dopant (e.g., As, Sb, or P) to form an n⁺ region that may be used as a low-resistance contact region for the cathode of the APD. The p⁺ region above the p-type multiplication layer may be formed in the second p⁻ epi layer by, for example, implanting a p-type dopants into a surface region of the second p⁻ epi layer using an implant mask, and may be used as a low-resistance contact region for the anode of the APD. In some examples, a shallow trench isolation (STI) region may be formed between the p⁺ region and the n⁺ region to reduce leakage. The n⁺ buried layer, the p-type multiplication layer, the second p⁻ epi layer above the p-type multiplication layer, and the p⁺ region may form a p⁺/p⁻/p/n⁺ junction structure of the APD.

In block 770, back end of line processes may be performed to form electrical connections with the n⁺ region and p⁺ region. For example, one or more dielectric layers (e.g., oxide layers) may be deposited on the semiconductor layer stack with APD formed therein. Vias may be formed in the one or more dielectric layers by, for example, selective etching and metal deposition. One or more metal layers (e.g., copper or aluminum layers) may be deposited and patterned on the one or more dielectric layers to form metal interconnects. The metal interconnects may include at least an anode and a cathode for the APD, and may be coupled to the n⁺ region and p⁺ region though one or more metal interconnects and one or more vias to apply a reverse bias to the APD. As described above, the metal interconnects and vias may also be used to connect the APD to other devices fabricated on the same substrates, such as CMOS and/or LDMOS circuits.

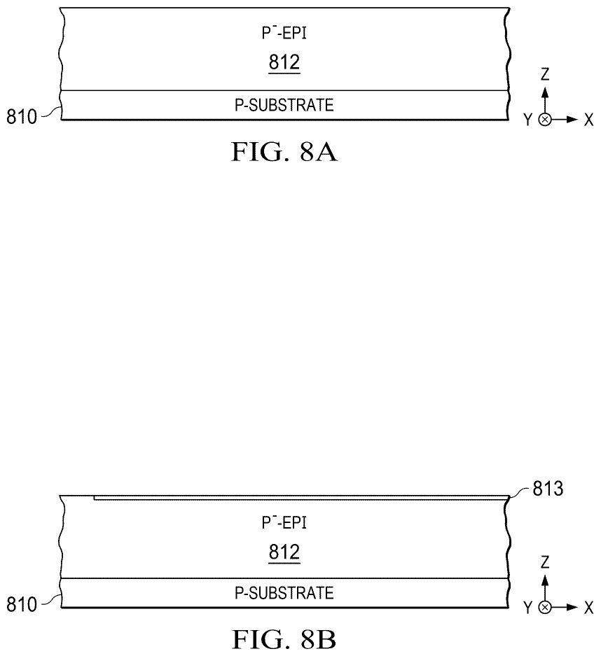

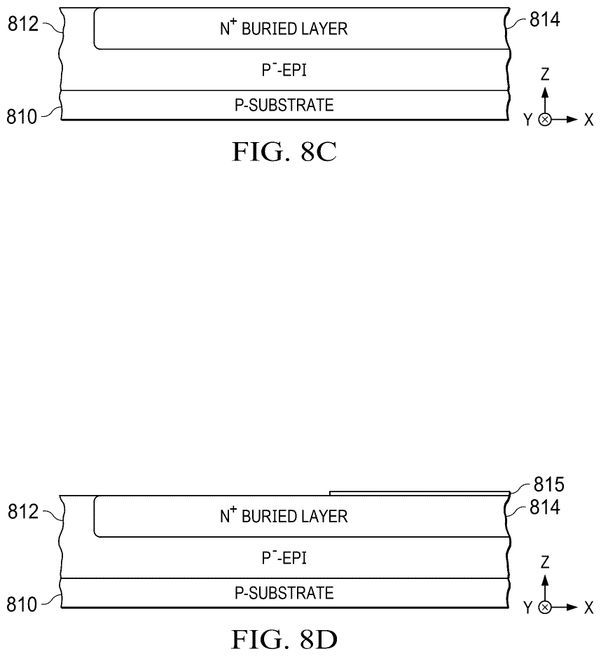

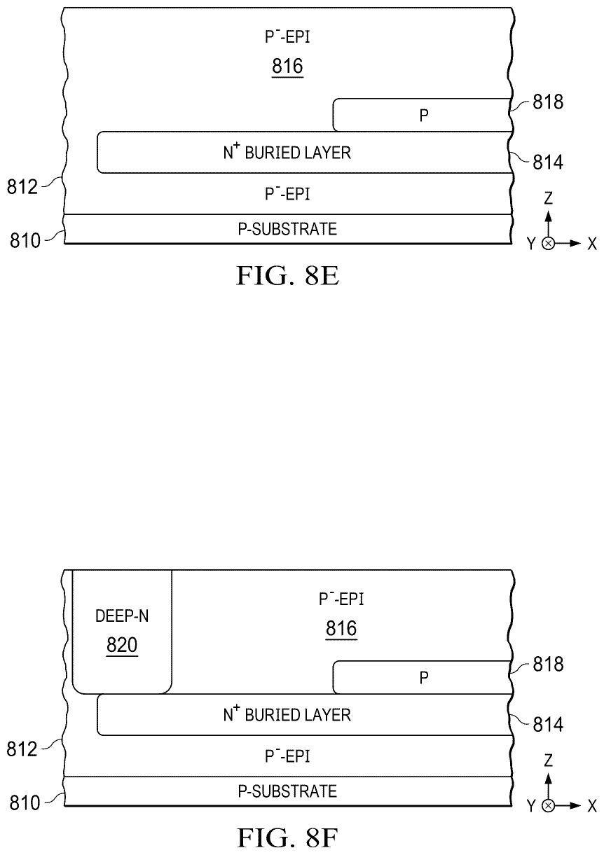

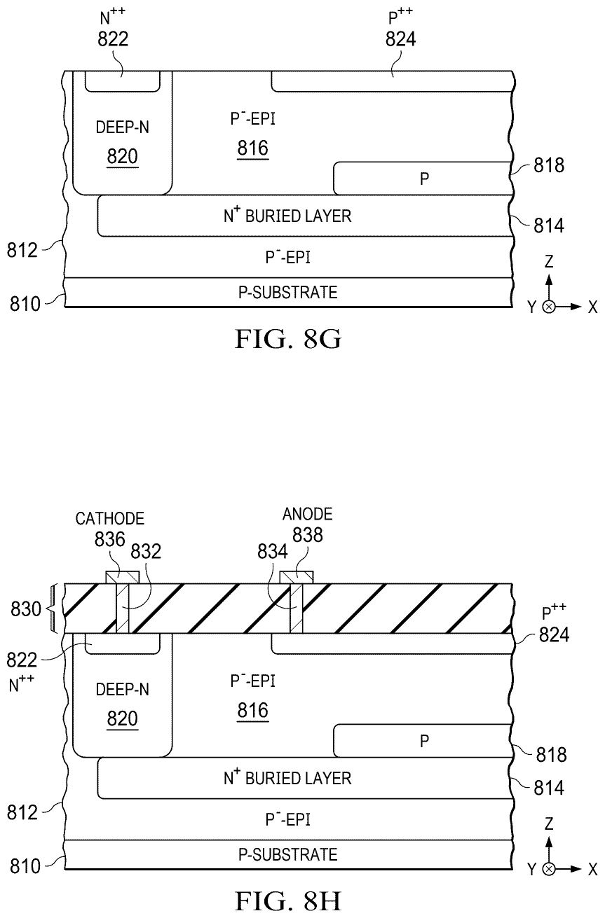

FIGS. 8A-8H illustrate an example of a process of fabricating an APD according to the flowchart of FIG. 7. FIG. 8A illustrates an example of a semiconductor wafer or die including a p-type substrate 810 and a lightly doped p-type epitaxial (p⁻ epi) layer 812 grown on p-type substrate 810. The semiconductor wafer or die shown in FIG. 8A may be fabricated using operations described above with respect to block 710 of FIG. 7. P-type substrate 810 and p⁻ epi layer 812 may include a same base semiconductor material. In one example, p-type substrate 810 may be a single crystalline silicon wafer doped with boron, and p⁻ epi layer 812 may be a silicon epitaxial layer with boron incorporated during or after the epitaxial growth.

FIG. 8B illustrates an example of a heavily doped n-type (n⁺) region 813 formed at a surface region of p⁻ epi layer 812. N⁺ region 813 may be formed using a mask and operations described above with respect to, for example, block 720 of FIG. 7. The n-type dopants in n⁺ region 813 may include, for example, As, Sb, P, or a combination thereof, and may be incorporated into p⁻ epi layer 812 by diffusion or one or more ion implanting processes. For example, as described above, n⁺ region 813 may be formed by implanting arsenic and/or antimony into p⁻ epi layer 812, and optionally implanting phosphorus deeper into p⁻ epi layer 812.

FIG. 8C shows that the semiconductor wafer or die may optionally be annealed at an elevated temperature (e.g., about 1150° C. to about 1225° C.) for a time period (e.g., at least about 30 minutes) as described above with respect to block 720 of FIG. 7, such that the implanted n-type dopants in n⁺ region 813 may diffuse deeper into p⁻ epi layer 812 to form an n⁺ buried layer 814.

FIG. 8D shows that p-type dopants such as boron may be implanted into a region 815 of n⁺ buried layer 814, for example, using an implant mask (not shown in FIG. 8D), as described above with respect to, for example, block 730 of FIG. 7. The energy and dose of the p-type dopants may be selected based on, for example, the doping concentration of the n-type dopants in n) buried layer 814, the target reverse bias voltage for avalanche multiplication, the total thermal budget of subsequent processes that may cause diffusion of the p-type dopants, and the like. As described above, in one example, the p-type dopants may be implanted into the region of n⁺ buried layer 814 at a dose between about 3.4×10¹³ cm⁻² and about 6.1×10¹³ cm⁻² (e.g., about 4.3×10¹³ cm⁻²) and an energy between about 70 keV and 110 keV (e.g., about 95 keV), in order to fabricate an APD with a breakdown voltage between about 30 V and about 50 V.

In FIG. 8E, a p⁻ epi layer 816 may be grown on p⁻ epi layer 812 and n⁺ buried layer 814 as described above with respect to, for example, block 740 of FIG. 7. In some examples, before growing p⁻ epi layer 816, an etch process may be performed to clean the surface of p⁻ epi layer 812 and n⁺ buried layer 814. P⁻ epi layer 816 may include silicon and p-type impurities (e.g., boron) incorporated during or after the epitaxial growth of p⁻ epi layer 816. Therefore, n⁺ buried layer 814 may be buried between p⁻ epi layer 812 and p⁻ epi layer 816. During the epitaxial growth, the n-type dopants and p-type dopants in n⁺ buried layer 814 may diffuse deeper into p⁻ epi layer 812 and may also diffuse into p⁻ epi layer 816, due to the elevated temperature during the epitaxial growth. In some examples, after growing p⁻ epi layer 816, the semiconductor wafer or die may optionally be annealed at an elevated temperature (e.g., between about 1100° C. and about 1200° C.) for a time period (e.g., 30 minutes or more), during which the n-type dopants and p-type dopants in n⁺ buried layer 814 may diffuse deeper into p⁻ epi layer 812 and may also diffuse into p⁻ epi layer 816. Since the p-type dopants (e.g., boron) may have a higher diffusion constant than the n-type dopants (e.g., As or Sb), more p-type dopants may diffuse deeper into p⁻ epi layer 816 to form a p-type multiplication region 818 above n⁺ buried layer 814. In one example, after the annealing process is complete, a peak doping concentration in n⁺ buried layer 814 may be greater than about 5×10¹⁸ cm⁻³, such as close to about 1×10¹⁹ cm⁻³, while a peak doping concentration in p-type multiplication region 818 may be, for example, greater than about 1×10¹⁶ cm⁻³. P-type multiplication region 818 in p⁻ epi layer 816 may form a PN junction with n⁺ buried layer 814, and may be used as the p-type multiplication layer of the APD.

In FIG. 8F, at least one deep n contact 820 may be formed in p⁻ epi layer 816 and in contact with an edge region of n⁺ buried layer 814. Deep n contact 820 may be formed using, for example, operations described above with respect to block 750 of FIG. 7. Deep n contact 820 may include, for example, a deep n-well formed by implant and anneal processes, or a deep trench with a self-aligned sinker along sidewalls of the deep trench and an electrically conductive material (e.g., polysilicon) filling the deep trench as described above.

FIG. 8G shows an n⁺⁺ (or n⁺) region 822 formed in deep n contact 820, and a p⁺⁺ (or p⁺ region 824 formed in a region of p⁻ epi layer 816 above p-type multiplication layer 818, using operations described above with respect to, for example, block 760 of FIG. 7. N⁺⁺ region 822 may be formed by implantation or diffusion of an n-type dopant such as P, Sb, or As, and may be used as a low-resistance cathode contact. P⁺⁺ (or p⁺) region 824 may be formed by implantation or diffusion of a p-type dopant such as boron, and may be used as a low-resistance anode contact. P⁺⁺ region 824, a region of p⁻ epi 816 below p⁺⁺ region 824, p-type multiplication layer 818, and n⁺ buried layer 814 may form a p⁺/p⁻/p/n⁺ junction structure of the APD.

FIG. 8H shows that electrical interconnects may be formed in or on one or more dielectric layer 830 (e.g., silicon oxide layers) using BEOL processes described above with respect to, for example, block 770 of FIG. 7. For example, a cathode 836 may be electrically coupled to n⁺⁺ region 822 through at least one via 832 formed in a dielectric layer 830, whereas an anode 838 may be electrically coupled to an edge region of p⁺⁺ region 824 through at least one via 834 formed in dielectric layer 830. As described above with respect to, for example, FIGS. 2 and 3, CMOS circuits, BiCMOS circuits, and/or LDMOS circuits may be fabricated on the semiconductor wafer or die using similar processes.

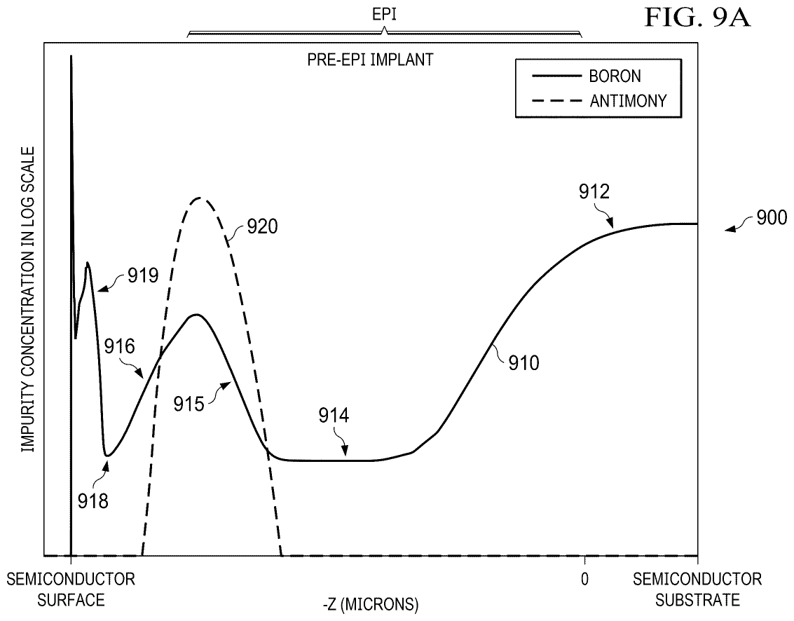

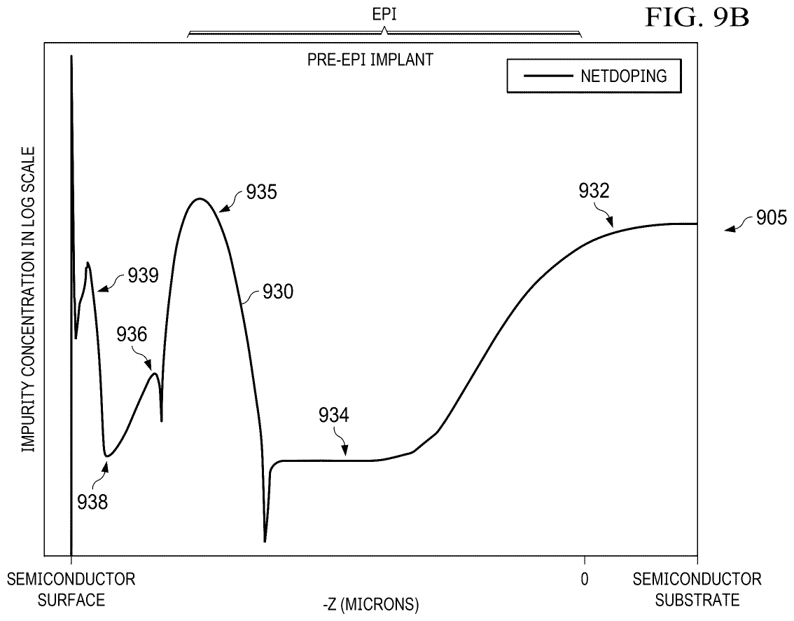

FIG. 9A is a diagram 900 illustrating n-dopant and p-dopant concentration profiles of an example of an APD (e.g., shown in FIG. 8G or 8H) where the multiplication layer (e.g., p-type multiplication region 818) of the APD may be formed by implanting p-type dopants before the growth of an epitaxial layer (e.g., p⁻ epi layer 816). The horizontal axis of diagram 900 corresponds to the −z direction (e.g., the surface normal direction of p-type substrate 810) shown in FIG. 8H, where a position with a value 0 on the horizontal axis may correspond to the interface between p-type substrate 810 and p⁻ epi layer 812. The vertical axis corresponds to the impurity (dopant) concentration (in log scale) in unit volume (e.g., cm⁻³). An impurity concentration profile 910 shows the p-dopant (e.g., boron) concentration in the semiconductor layer stack of the APD, while an impurity concentration profile 920 shows the n-dopant (e.g., Sb) concentration in the semiconductor layer stack of the APD.

A region 912 of impurity concentration profile 910 shows the concentration of boron in p-type substrate 810. A region 914 of impurity concentration profile 910 shows the concentration of boron in p⁻ epi layer 812. A region 915 of impurity concentration profile 910 shows the concentration of boron in n⁺ buried layer 814. A region 916 of impurity concentration profile 910 shows the concentration of boron in p-type multiplication region 818. A region 918 of impurity concentration profile 910 shows the concentration of boron in p⁻ epi layer 816. A region 919 of impurity concentration profile 910 shows the concentration of boron in p⁺⁺ region 824. Impurity concentration profile 910 shows that the concentration of boron may have a peak in n⁺ buried layer 814 and may gradually decrease towards p⁻ epi layer 816 and p⁻ epi layer 812, due to the diffusion from n⁺ buried layer 814. Thus, the peak concentration of boron in n⁺ buried layer 814 is higher than the peak concentration of boron in p-type multiplication region 818.

Impurity concentration profile 920 shows that the n-type dopants (e.g., Sb) are mainly in n⁺ buried layer 814, and may have a concentration higher than the p-type dopants in n⁺ buried layer 814. Impurity concentration profile 920 also shows that the n-type dopants may diffuse into p⁻ epi layer 812, p-type multiplication region 818, and p⁻ epi layer 816, but may have a lower concentration than the p-type dopants in p⁻ epi layer 812, p-type multiplication region 818, and p⁻ epi layer 816, such that p-type multiplication region 818 is effectively p-doped, and p⁻ epi layer 812 and p⁻ epi layer 816 are lightly p-doped.

FIG. 9B is a diagram 905 illustrating an impurity concentration profile 930 of the net dopants in the example of the APD of FIG. 9A. The horizontal axis of the diagram corresponds to the −z direction shown in FIG. 8G or 8H, where a position with a value 0 on the horizontal axis may correspond to the interface between p-type substrate 810 and p⁻ epi layer 812. The vertical axis corresponds to the net impurity concentration (in log scale) in unit volume (e.g., cm⁻³). A region 932 of impurity concentration profile 930 shows the concentration of the p-type dopant (e.g., B) in p-type substrate 810. A region 934 of impurity concentration profile 930 shows the net concentration of the p-type dopant (e.g., B) in p⁻ epi layer 812. A region 935 of impurity concentration profile 930 shows the net concentration of the n-type dopant (e.g., As or Sb) in n⁺ buried layer 814. A region 936 of impurity concentration profile 930 shows the net concentration of the p-type dopant (e.g., B) in p-type multiplication region 818. A region 938 of impurity concentration profile 930 shows the concentration of the p-type dopant (e.g., B) in p⁻ epi layer 816. A region 939 of impurity concentration profile 930 shows the concentration of the p-type dopant (e.g., B) in p⁺⁺ region 824.

As described above, in some examples, the PN junction of an APD may be formed by an implanted p-type multiplication layer and an n-type extension layer formed by the diffusion of n-type dopants from an n⁺ buried layer towards the implanted p-type multiplication layer. For example, after forming an n⁺ buried layer that includes a first n-type dopant (e.g., Sb), a second n-type dopant (e.g., phosphorus (P)) that has a higher diffusion constant than the first n-type dopant may be implanted into a region of the n⁺ buried layer. An intrinsic or lightly p-doped epitaxial layer may be grown over the n⁺ buried layer. During the epitaxial growth of the intrinsic or lightly p-doped epitaxial layer and/or the subsequent annealing processes, the second n-type dopant having the higher diffusion constant may diffuse from the region of the n⁺ buried layer into the intrinsic or lightly p-doped epitaxial layer at a rate faster than the first n-type dopant. Therefore, a region of the intrinsic or lightly p-doped epitaxial layer adjacent to the n⁺ buried layer may have a higher concentration of n-type dopants (e.g., mostly the second n-type dopant) than p-type dopants. As such, the region of the intrinsic or lightly p-doped epitaxial layer adjacent to the n⁺ buried layer may become an n-doped extension region. A subsequent p-type implanting (e.g., using B) may be performed from the top of the intrinsic or lightly p-doped epitaxial layer to form the multiplication layer of an APD. The multiplication layer may form a junction with the n-doped extension region. Since the p-type dopants are not implanted into a region adjacent to the n⁺ buried layer that may be deep under the top surface of the intrinsic or lightly p-doped epitaxial layer, the energies of the p-type dopants may be low, and thus may be easy to achieve and may cause less damage to the crystalline structure of the semiconductor layer. By selecting the proper dose and energy for implanting the second n-type dopant and/or the p-type dopant, an n⁺/n/p junction with the target impurity concentration profile and layer thicknesses and locations may be formed to achieve the desired APD performance.

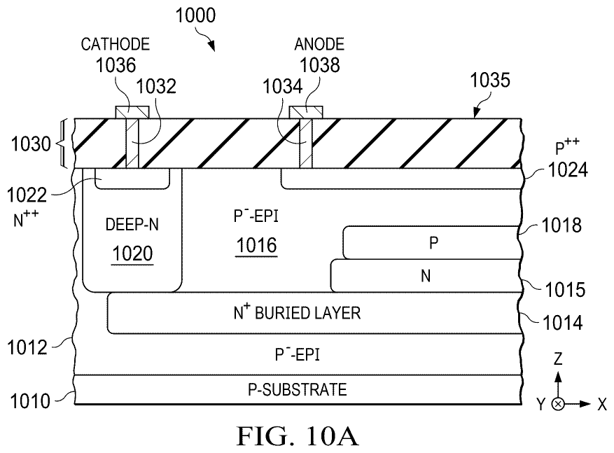

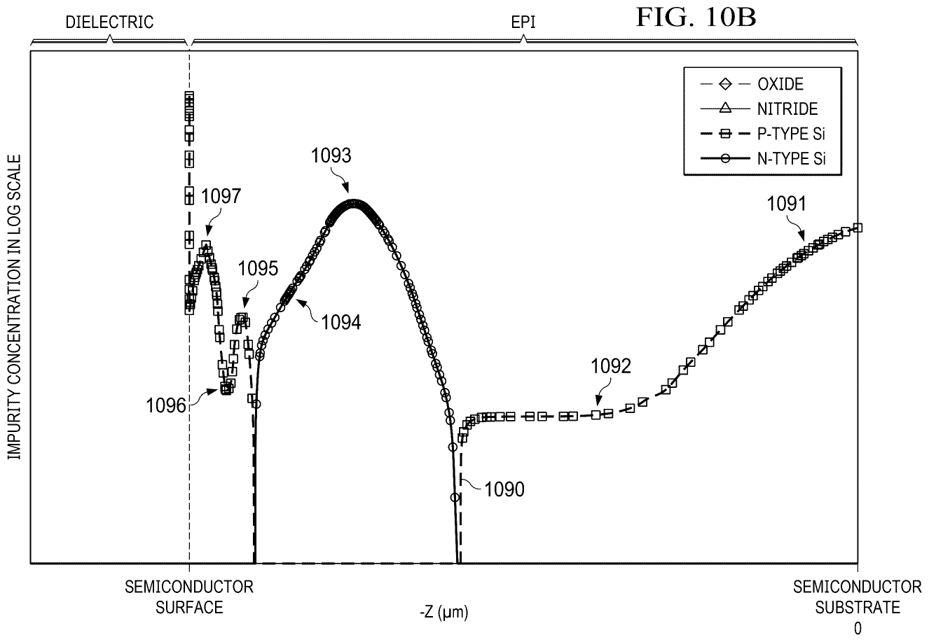

FIG. 10A is a cross-sectional view of an example of an APD 1000. APD 1000 may be a planar-based avalanche photodiode with the anode and cathode on a same side of a semiconductor substrate. APD 1000 may be similar to APD 101, 202, or 302, or the APD shown in FIG. 5H or 8H, but may include an additional n-type extension layer between the p-type multiplication layer and the n⁺ buried layer. In the illustrated example, APD 1000 may include a p-type substrate 1010, a lightly p-doped epitaxial layer (p⁻ epi layer) 1012 grown on p-type substrate 1010, and a junction structure formed on p⁻ epi layer 1012. The junction structure may include a heavily doped n-type buried layer (n⁺ buried layer) 1014 at least partially formed in a portion of p⁻ epi layer 1012 through the incorporation (e.g., implantation) of n-type dopants, such as As, Sb, and/or P. For example, n⁺ buried layer 1014 may be implanted with at least two different n-type dopants (e.g., Sb and P) having different diffusion constants. The junction structure may also include a p⁻ epi layer 1016 grown over p⁻ epi layer 1012 and n⁺ buried layer 1014. The junction structure may further include a p-type multiplication layer 1018, an n-type extension layer 1015 between p-type multiplication layer 1018 and n⁺ buried layer 1014, and a heavily doped p-type (p⁺⁺) region 1024 formed in p⁻ epi layer 1016. P-type multiplication layer 1018 may be formed by implanting p-type dopants from the top surface of p⁻ epi layer 1016. The portion of p⁻ epi layer 1016 between p⁺⁺ region 1024 and p-type multiplication layer 1018 may function as the absorption region. N-type extension layer 1015 may be formed by the diffusion of n-type dopants (e.g., phosphorus, which may have a higher diffusion constant than Sb) from n⁺ buried layer 1014 towards p-type multiplication layer 1018. P⁺⁺ region 1024 may be formed by implanting or diffusing p-type dopants from the top surface of p⁻ epi layer 1016.

APD 1000 may also include a deep n contact 1020 (e.g., a deep n-well or a deep trench filled with an electrically conductive material) formed within a region of p⁻ epi layer 1016. Deep n contact 1020 may be in contact with edge regions of n⁺ buried layer 1014. In some examples, deep n contact 1020 may surround p-type multiplication layer 1018. A heavily doped n-type (n⁺⁺) region 1022 may be formed within deep n contact 1020. N⁺⁺ region 1022 and p⁺⁺ region 1024 may be used to form a low resistance cathode contact and a low resistance anode contact, respectively, and may be used to reversely bias APD 1000 at a voltage close to a breakdown voltage to facilitate impact ionization and avalanche multiplication.

APD 1000 may further include a dielectric layer 1030 deposited on p⁻ epi layer 1016. A cathode 1036 and an anode 1038 may be formed on or in dielectric layer 1030. Cathode 1036 may be electrically coupled to n⁺⁺ region 1022 by one or more electrical interconnects 1032 (e.g., a metal via). Similarly, anode 1038 may be electrically coupled to p⁺⁺ region 1024 by one or more electrical interconnects 1034 (e.g., a metal via). Cathode 1036 and anode 1038 may be connected to a voltage source. At least a portion 1035 of dielectric layer 1030 may be transparent to photons of light within a wavelength range, such as visible light or infrared light. Therefore, the photons may pass through dielectric layer 1030 and be absorbed in p⁻ epi layer 1016 to generate charge carriers (e.g., electrons and holes), and the photo-generated charge carriers may be moved towards respective electrodes. For example, electrons may flow towards the more positively biased n-type extension layer 1015 and n⁺ buried layer 1014, and thus may enter p-type multiplication layer 1018 where the magnitude of the electric field may be relatively high. Due to the relatively high electric field in p-type multiplication layer 1018, a charge carrier entering p-type multiplication layer 1018 may gain sufficient energy to generate one or more secondary electron-hole pairs through impact ionization, thereby achieving carrier multiplication.

FIG. 10B is a diagram illustrating an example of an impurity concentration profile of the net dopants in an example of the APD shown in FIG. 10A. The horizontal axis of the diagram corresponds to the −z direction shown in FIG. 10A, where a position with a value 0 on the horizontal axis may correspond to a region or a surface of p-type substrate 1010. The vertical axis corresponds to the impurity concentration (in log scale) in unit volume (e.g., cm⁻³). A region 1091 of impurity concentration profile 1090 shows the concentration of the p-type dopant (e.g., B) in p-type substrate 1010. A region 1092 of impurity concentration profile 1090 shows the net concentration of the p-type dopant (e.g., B) in p⁻ epi layer 1012. A region 1093 of impurity concentration profile 1090 shows the net concentration of the n-type dopant (e.g., As, Sb, or P) in ⁺n buried layer 1014. A region 1094 of impurity concentration profile 1090 shows the net concentration of the n-type dopant (e.g., P and/or Sb) in n-type extension layer 1015. A region 1095 of impurity concentration profile 1090 shows the net concentration of the p-type dopant (e.g., B) in p-type multiplication layer 1018. A region 1096 of impurity concentration profile 1090 shows the concentration of the p-type dopant (e.g., B) in p⁻ epi layer 1016. A region 1097 of impurity concentration profile 1090 shows the concentration of the p-type dopant (e.g., B) in p⁺⁺ region 1024.

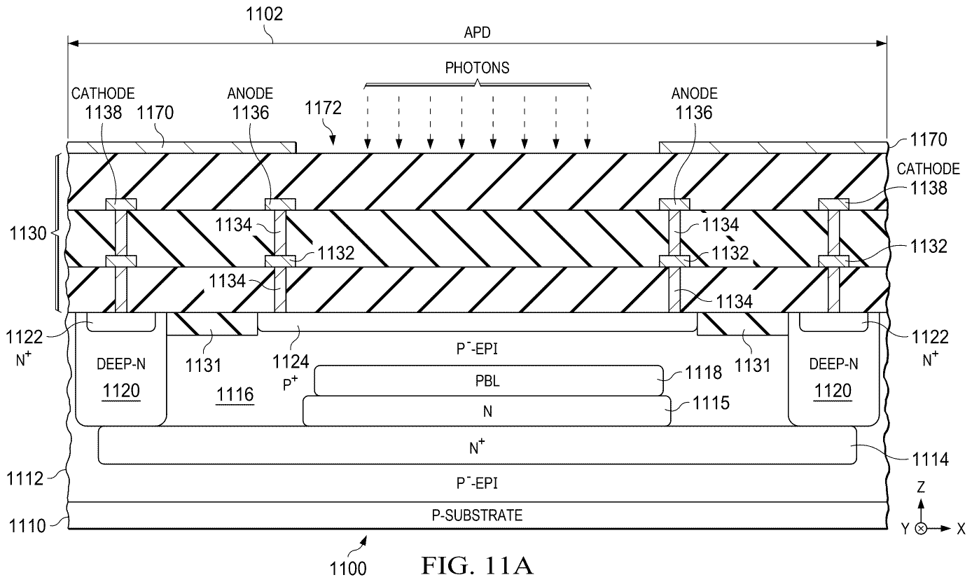

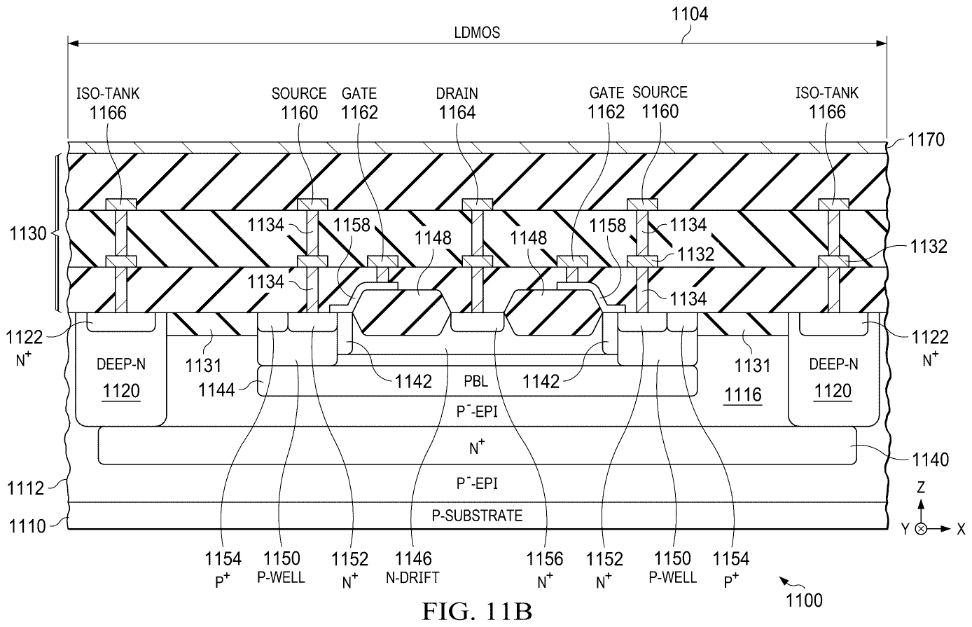

FIG. 11A and FIG. 11B are cross-sectional views of an example of an integrated circuit 1100 including an APD 1102 and an LDMOS circuit 1104 on a substrate or die. Integrated circuit 1100 may be similar to integrated circuit 300 shown in FIG. 3A and FIG. 3B. For example, LDMOS circuit 1104 may be similar to LDMOS circuit 304, and may include, for example, power devices such as high-voltage transistors or diodes. APD 1102 may be similar to APD 302, but may include an additional n extension layer between the p-type multiplication layer and the n⁺ buried layer as described above with respect to FIG. 10A, and the p-type multiplication layer in APD 1102 and the p-type buried layer of LDMOS circuit 1104 may be fabricated in the same process.

As illustrated in FIG. 11A and FIG. 11B, APD 1102 and LDMOS circuit 1104 may be fabricated in a same die on a same substrate 1110. As described above, substrate 1110 may be a p-doped substrate formed by doping the undoped single crystal silicon of a silicon substrate by implantation or diffusion of p-type dopants (e.g., boron). A lightly p-doped epitaxial layer (p⁻ epi layer) 1112 may be epitaxially grown on p-doped substrate 1110. A first heavily doped n-type buried region (first n⁺ buried region) 1114 may be at least partially formed in a first region of p⁻ epi layer 1112 through the incorporation (e.g., implantation) of n-type dopants, such as As, Sb, and/or P. A second heavily doped n-type buried region (second n⁺ buried region) 1140 may be at least partially formed in a second region of p⁻ epi layer 1112 through the incorporation (e.g., implantation) of n-type dopants, such as As, Sb, and/or P. In one example, after p⁻ epi layer 1112 is grown, first n⁺ buried region 1114 and second n⁺ buried region 1140 may be formed at or near the surface of p⁻ epi layer 1112, and another p⁻ epi layer 1116 may be grown on top of p⁻ epi layer 1112 (and n⁺ buried regions 1114 and 1140), such that first n⁺ buried region 1114 and second n⁺ buried region 1140 may be buried under p⁻ epi layer 1116. For examples, first n⁺ buried region 1114 and second n⁺ buried region 1140 may be formed by heavily doping the first region and the second region of p⁻ epi layer 1112 at or near the surface of p⁻ epi layer 1112 with a first n-type dopant (e.g., Sb or As) via implantation or diffusion. The n-type dopant may diffuse deeper into p⁻ epi layer 1112 during a thermal annealing process and/or the epitaxial growth of p⁻ epi layer 1116, and may partially diffuse into p⁻ epi layer 1116 during the epitaxial growth of p⁻ epi layer 1116 or a subsequent thermal annealing process, thereby forming first n⁺ buried region 1114 and second n⁺ buried region 1140 in p⁻ epi layer 1112 and/or p⁻ epi layer 1116.

In addition, a portion of first n⁺ buried region 1114 may be implanted with a second n-type dopant (e.g., P) that may have a higher diffusion constant than the first n-type dopant. During the thermal annealing process and/or the epitaxial growth of p⁻ epi layer 1116, the second n-type dopant may diffuse from the heavily doped n⁺ buried region 1114 into p⁻ epi layer 1116 at a faster rate than the first n-type dopant. Therefore, a region of the lightly doped p⁻ epi layer 1116 adjacent to n⁺ buried region 1114 may have a higher concentration of n-type dopants than p-type dopants. As such, the region of p⁻ epi layer 1116 layer adjacent to n⁺ buried region 1114 may become an n-type extension layer 1115. By selecting the proper dose and energy for implanting the second n-type dopant, the target impurity concentration profile and layer thickness and location of n-type extension layer 1115 may be achieved to achieve the target APD performance.

Deep n contacts 1120 (e.g., deep n-wells or deep trenches filled with electrically conductive materials) may be formed within p⁻ epi layer 1116, and may be in contact with edge regions of first n⁺ buried region 1114 and edge regions of second n⁺ buried region 1140. In some examples as shown in FIG. 11A and FIG. 11B, a deep n contact 1120 and first n⁺ buried region 1114 may form a junction isolation structure that isolates a first region of p⁻ epi layer 1116 above first n⁺ buried region 1114, while another deep n contact 1120 and second n⁺ buried region 1140 may form a junction isolation structure that isolates a second region of p⁻ epi layer 1116 above second n⁺ buried region 1140. A heavily doped n-type (n⁺) region 1122 may be formed within each deep n contact 1120, and may be used to form a low resistance cathode contact.

In the first region of p⁻ epi layer 1116 above first n⁺ buried region 1114, a p-type region 1118 (e.g., a p-type buried layer (PBL)) may be formed by, for example, implanting p-type dopants after the growth of p⁻ epi layer 1116, as described in more detail below, so that p-type region 1118 and n-type extension layer 1115 may form a PN junction, and p-type region 1118 can be configured as a multiplication layer of an APD. A heavily doped p-type (p⁺) region 1124 may be formed within the first region of p⁻ epi layer 1116 by, for example, implanting a p-type dopants into a surface region of p⁻ epi layer 1116, using an implant mask. The heavily doped p-type (p⁺) region 1124 may be used to form a low resistance anode contact. In the illustrated example, a shallow trench isolation (STI) region 1131 may be formed between p⁺ region 1124 and deep n contact 1120, to reduce leakage between p⁺ region 1124 and deep n contact 1120. P⁺ region 1124, p⁻ epi layer 1116, p-type region 1118, n-type extension layer 1115, and first n⁺ buried region 1114 may form a vertical layer stack (e.g., along the z axis) that includes a p⁺/p⁻/p/n/n⁺ junction structure.

In the second region of p⁻ epi layer 1116 above second n⁺ buried region 1140, LDMOS circuit 1104 may be formed using standard LDMOS processes. LDMOS circuit 1104 may include a high-voltage power transistor that can withstand a high voltage between the source and drain when the transistor is turned off. The power transistor in the illustrated example may be an n-channel double-diffused MOS field-effect transistor (MOSFET) fabricated using multiple ion implantation and annealing processes. As illustrated, the LDMOS transistor may include a heavily doped n-type (n⁺) drain region 1156 surrounded by a relatively lightly doped n-drift region 1146, a polysilicon gate 1158 on gate oxide 1148 formed by local oxidation of silicon (LOCOS), and a heavily doped n-type (n⁺) source region 1152 formed in a diffused p-well 1150. P-well 1150 may be implanted with n-type dopants (e.g., As or Sb) and p-type dopants (e.g., B). The n-type dopants may form source region 1152, whereas the p-type dopants may diffuse out laterally to form a p-type diffusion region 1142. P-type diffusion region 1142 and n-drift region 1146 may form a lateral PN junction between the drain and source of the LDMOS transistor. A region of p-well 1150 may be heavily doped with a p-type dopant to form a p⁺ region 1154. The doping density of n-drift region 1146 may be selected such that n-drift region 1146 may be depleted when the LDMOS transistor is turned off and a high voltage is applied to the drain, and may also provide low on-state resistance (RDSon) together with the highly doped n) drain region when the LDMOS transistor is turned on, thereby achieving high breakdown voltages, low on-state resistance, and good hot carrier injection reliability.

As described above, breakdown in conventional LDMOS transistors may primarily occur due to high electric fields in the region under the gate. The PN junction between p-type diffusion region 1142 and n-drift region 1146 may be the weakest point for breakdown, and may also define the on-state resistance characteristic of the device. The high electric fields can be significantly lowered by utilizing the RESURF effect, which may be used to control the total charge in n-drift region 1146 in order to maximize the device breakdown voltage, while achieving low on-state resistance. In the example shown in FIG. 11A and FIG. 11B, the LDMOS transistor may include a relatively lightly doped p-type buried layer 1144 under n-drift region 1146 and connected to the source of the LDMOS transistor through p-well 1150 and p⁺ region 1154. Therefore, n-drift region 1146, p⁻ epi layer 1116, and p-type buried layer 1144 under n-drift region 1146 may form a vertical PN junction between the drain and source of the LDMOS transistor. When the LDMOS transistor is turned off and a high voltage is applied to the drain, the n-drift region 1146 may be depleted both in the horizontal direction due to the reversely biased PN junction between p-type diffusion region 1142 and n-drift region 1146, and in the vertical direction due to the reversely biased PN junction between n-drift region 1146 and p-type buried layer 1144, thereby enhancing the growth of the depletion layer at the surface (e.g., in n-drift region 346).

P-type buried layer 1144 may be formed using the same process and/or same implants used to form p-type region 1118, so that both layer 1144 and region 1118 can have the same dopants (e.g., both are doped with boron) at the same (or different) concentrations. Device parameters such as doping density, layer thickness, and structural geometry may be selected such that, when the drain voltage is high, the vertical depletion may extend to the surface of the silicon to completely deplete n-drift region 1146. Once this occurs, n-drift region 1146 under the gate edge may effectively be isolated from n⁺ drain region 1156, and the electric field under the gate edge may remain approximately constant as the drain voltage is increased. Therefore, the lateral (surface) electric field of the PN junction between p-type diffusion region 1142 and n-drift region 1146 may be reduced, and the LDMOS transistor may break down at a voltage that is mainly determined by the PN junction between n-drift region 1146 and p-type buried layer 1144, which can be high. Due to the RESURF effect, n-drift region 1146 can be relatively highly doped to reduce on-state resistance, without reducing the breakdown voltage.

Back end of line processes may be performed to form electrical interconnects that connect the individual devices. For example, one or more dielectric layers 1130 (e.g., silicon oxide layers) may be deposited on the substrate with APD 1102 and LDMOS circuit 1104 formed thereon. Vias 1134 may be formed in the one or more dielectric layers 1130 by, for example, selective etching and metal deposition, to connect metal interconnects 1132 formed in one or more patterned metal layers. For example, an anode 1136 and a cathode 1138 may be formed in or on a dielectric layer 1130 to apply the reverse bias to the p⁺/p⁻/p/n/n⁺ junction of APD 1102. Cathode 1138 may be electrically coupled to n⁺ region 1122 by one or more electrical interconnects (e.g., vias 1134 and/or metal interconnects 1132). Anode 1136 may be electrically coupled to p⁺ region 1124 by one or more electrical interconnects (e.g., vias 1134 and/or metal interconnects 1132). Similarly, one or more vias 1134 and/or one or more metal interconnects 1132 may be used to connect a source terminal 1160 to the source region 1152 of the LDMOS transistor, connect a gate terminal 1162 to polysilicon gate 1158 of the LDMOS transistor, connect a drain terminal 1164 to the drain region (e.g., n⁺ regions 1156) of the LDMOS transistor, and connect an isolation terminal 1166 to n⁺ regions 1122 and deep n contacts 1120 (e.g., deep n-wells) that surround and isolate the LDMOS transistor. Other connections between different devices on a die or substrate may also be made using one or more vias 1134 and/or one or more metal interconnects 1132.

A light transmission window 1172 on top of APD 1102 may be formed in a light blocking layer 1170 (e.g., a metal layer), such that light may pass through light transmission window 1172 and detected by the underlying APD 1102. Light may be prevented from passing through other regions of light blocking layer 1170, for example, to reduce the interference of photo-generated charge carriers on the performance of other circuits and reduce stray light that may reach APD 1102 from other regions. Operations of APD 1102 may be similar to operations of APD 101 or 202 described above, and thus are not described again with respect to FIG. 11A and FIG. 11B.

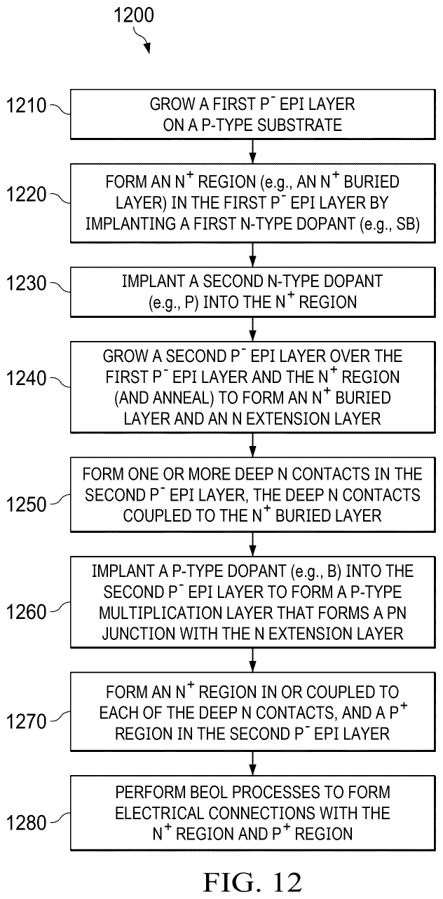

FIG. 12 is a flowchart 1200 illustrating an example of a process of fabricating an APD. Operations in block 1210 may be similar to operations in block 410 or 710, and may include growing a first lightly doped p-type epitaxial layer (p⁻ epi layer) on a p-type substrate. For example, p-type dopants (e.g., boron) may be incorporated into undoped single crystal silicon of a silicon substrate by implantation or diffusion to form the p-type substrate. The first p⁻ epi layer may then be grown on the p-type substrate. The epitaxy process may use, for example, silane, dichlorosilane, or other silicon-containing reagents. The epitaxy process may also use a boron containing reagent such as diborane to include p type dopants in the first p⁻ epi layer. Alternatively, p-type dopants such as boron may be implanted into the first p⁻ epi layer after the epitaxy process is completed. In some examples, the first p⁻ epi layer may have a resistivity of about 1 ohm-cm to about 100 ohm-cm.

Operations in block 1220 may be similar to operations in block 420 or 720, and may include forming a heavily doped n-type (n⁺) region in the first p⁻ epi layer by implanting an n-type dopant (e.g., Sb) through an implant mask as described above. For example, the n⁺ region may be formed in a surface region of the first p⁻ epi layer through the incorporation (e.g., implantation or diffusion) of n-type dopants, such as As or Sb. In one example, the n-type dopants may be substantially all antimony, and may be implanted at a dose greater than about 5×10¹⁴ cm⁻², such as about 1×10¹⁵ cm⁻² to about 5×10¹⁵ cm⁻², and an energy less than about 50 keV. In some examples, a first thermal drive process may be performed to heat the first p⁻ epi layer to a temperature between about 1150° C. and about 1225° C. for at least about 30 minutes. The first thermal drive process may be performed in a furnace with an oxidizing ambient, and may cause the implanted n-type dopants to diffuse deeper into the first p⁻ epi layer to form an n⁺ buried layer.

In block 1230, a second n-type dopant (e.g., phosphorous) having a higher diffusion rate than the first n-type dopant (e.g., antimony) may be implanted into a portion of the n⁺ buried layer using an implant mask. The energy and dose of the second n-type dopant may be determined based on, for example, the thickness of a second p⁻ epi layer grown on the first p⁻ epi layer, the target reverse bias voltage for avalanche multiplication, the total thermal budget of subsequent processes that may cause phosphorous to diffuse, and the like. For example, when the dose of the second n-type dopant is higher, the reverse bias voltage for avalanche multiplication may be lower.

In block 1240, a second p⁻ epi layer may be grown over the first p⁻ epi layer and the n⁺ buried layer. In some examples, before growing the second p⁻ epi layer, an etch process may be performed to clean the surface of the first p⁻ epi layer and the n⁺ buried layer. The epitaxy process may use silane, dichlorosilane, or other silicon-containing reagents. The epitaxy process may also use a boron-containing reagent such as diborane to include p-type dopants in the second p⁻ epi layer. Alternatively, p-type dopants such as boron may be implanted into the second p⁻ epi layer after the epitaxy process is completed.

In some examples, after the growth of the second p⁻ epi layer, a second thermal drive process may be performed to heat the substrate to a temperature between about 1125° C. and about 1200° C. for at least about 120 minutes. The second thermal drive process may be performed in a furnace with a slightly oxidizing ambient. During the epitaxial growth process for growing the second p⁻ epi layer and/or the second thermal drive process, the n-type dopants in the n⁺ buried layer may diffuse into the first p⁻ epi layer and the second p⁻ epi layer. The second n-type dopant in the n⁺ region may diffuse from the heavily doped n⁺ buried layer into the second p⁻ epi layer at a faster rate than the first n-type dopant. Therefore, a region of the lightly doped second p⁻ epi layer adjacent to n⁺ buried layer may have a higher concentration of n-type dopants (e.g., mostly the second n-type dopant) than p-type dopants. As such, the region of the second p⁻ epi layer adjacent to the n⁺ buried layer may become an n-type extension layer. By selecting the proper dose and energy for implanting the second n-type dopant, the target impurity concentration profile and layer thickness and location of the n-type extension layer may be achieved to achieve the target APD performance.

In one example, the second p⁻ epi layer may have a thickness about 5 μm and a boron concentration about 2.0×10¹⁵ cm⁻³, and the n⁺ buried layer may have a antimony concentration about 1.0×10¹⁹ cm⁻³, phosphorus may be implanted into the first p⁻ epi layer at a dose between about 2.8×10¹⁴ cm⁻² and about 4.2×10¹⁴ cm⁻² and an energy between about 160 keV and about 200 keV, in order to form an APD with breakdown voltage between about 30 V and about 40 V. In contrast, under similar conditions, to form the n-type extension layer by implanting phosphorus from the top surface of the second p⁻ epi layer, phosphorus may be implanted into the second p⁻ epi layer at a dose greater about 2.0×10¹³ cm⁻² and an energy greater than about 4 MeV, which may be difficult or expensive to achieve, and may cause damages and defects in the crystalline structure of the semiconductor layer (e.g., the second p⁻ epi layer).

Operations in block 1250 may be similar to operations in block 450 or 750, and may include forming one or more deep n contacts (sinkers) in the second p⁻ epi layer, where the deep n contacts may be coupled to the n⁺ buried layer. In some examples, the deep n contacts may be in contact with edge regions of the n⁺ buried layer, and thus may, in combination with the n⁺ buried layer, form a junction isolation structure that isolates a region of the second p⁻ epi layer above the n⁺ buried layer from other circuits fabricated on the substrate, so that the APD may have lower noise and better performance. In one example, the deep n contacts may include deep n-wells formed by implanting dopants in one or more doses followed by activation anneal. In some examples, the deep n contacts may be formed by forming a deep trench down to the n⁺ buried layer, implanting dopants (e.g., at a slanted angle) into the second p⁻ epi layer along sidewalls of the deep trench, and subsequently filling the deep trench with an electrically conductive material such as polysilicon (e.g., by depositing a conformal layer of polysilicon and subsequently removing the polysilicon on the top surface of the second p⁻ epi layer using, for example, by a CMP process), as described above with respect to block 450 of FIG. 4.

Operations in block 1260 may be similar to operations in block 440, and may include implanting a p-type dopant (e.g., B) into the second p⁻ epi layer to form a p-type multiplication layer, which may form a PN junction with the n-type extension layer. Implanting the p-type dopant into the second p⁻ epi layer may be performed by, for example, forming an implant mask on the second p⁻ epi layer to expose a region of the second p⁻ epi layer, and implanting the p-type dopant into the exposed region of the second p⁻ epi layer using high-energy dopants so that the p-type dopants may penetrate into the second p⁻ epi layer (e.g., a few microns below the top surface of the second p⁻ epi layer). However, since the p-type dopants do not reach the n⁺ buried layer, the energies of the p-type dopants can be much lower than the energies of the p-type dopants used to form p-type multiplication layer 518. In one example, the p-type multiplication layer may be formed by implanting boron at an energy between about 1 MeV and 10 MeV (e.g., about 1.4 MeV), and a dose between about 1×10¹² cm⁻² and 50×10¹³ cm⁻², which may yield a breakdown voltage between about 30 V and 50 V. In some examples, an annealing process may be performed after implanting the p-type dopants into the second p⁻ epi layer, such that some p-type dopants may diffuse towards the n-type extension layer while some n-type dopants in the n-type extension layer and the n⁺ buried layer may diffuse further into the second p⁻ epi layer, thereby forming a PN junction between the n-type extension layer and the p-type multiplication layer.

Operations in block 1270 may be similar to operations in block 460 or 760, and may include forming an n⁺ region in or coupled to each of the one or more deep n contacts, and forming a p⁺ region in the second p⁻ epi layer above the p-type multiplication layer. For example, a region of each of the one or more deep n-wells may be implanted with an n-type dopant (e.g., As, Sb, or P) to form an n⁺ region that may be used as a low-resistance contact region for the cathode of the APD. The p⁺ region above the p-type multiplication layer may be formed by, for example, implanting a p-type dopant (e.g., B) into a surface region of the second p⁻ epi layer using an implant mask, and may be used as a low-resistance contact region for the anode of the APD. In some examples, a shallow trench isolation (STI) region may be formed between the p⁺ region and the n⁺ region to reduce leakage. The n⁺ buried layer, the n-type extension layer, the p-type multiplication layer, the second p⁻ epi layer above the p-type multiplication layer, and the p⁺ region may form an APD that includes a p⁺/p⁻/p/n/n⁺ junction structure.

In block 1280, BEOL processes may be performed to form electrical connections with the n⁺ region and p⁺ region as described above. For example, one or more dielectric layers (e.g., oxide layers) may be deposited on the semiconductor layer stack with APD formed therein. Vias may be formed in the one or more dielectric layers by, for example, selective etching and metal deposition. One or more metal layers (e.g., copper or aluminum layers) may be deposited and patterned on the one or more dielectric layers to form metal interconnects. The metal interconnects may include at least a cathode and an anode for the APD, which may be coupled to the n⁺ region and p⁺ region, respectively, though one or more metal interconnects and one or more vias, to apply a reverse bias to the APD. As described above, the metal interconnects and vias may also be used to connect the APD to other devices fabricated on the same substrates, such as CMOS and/or LDMOS circuits.

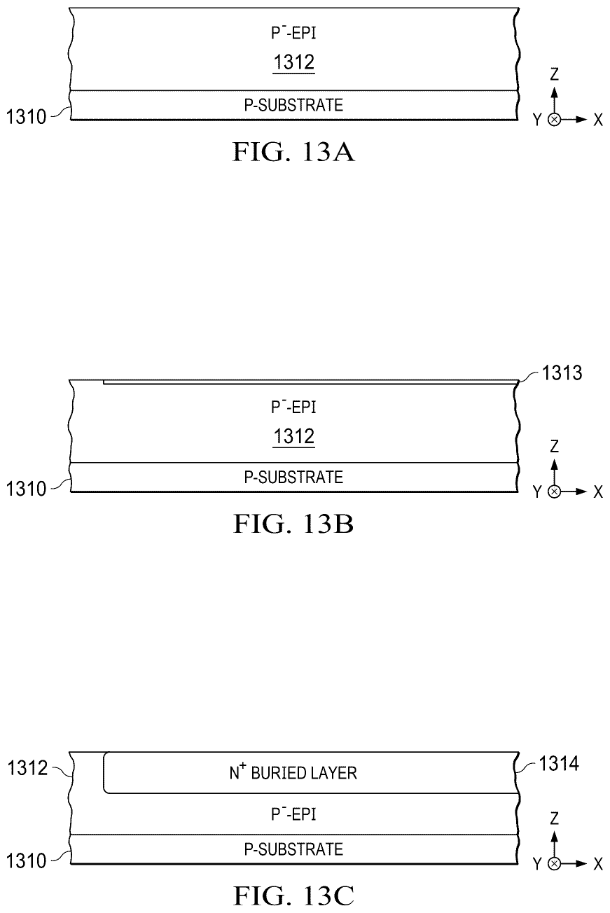

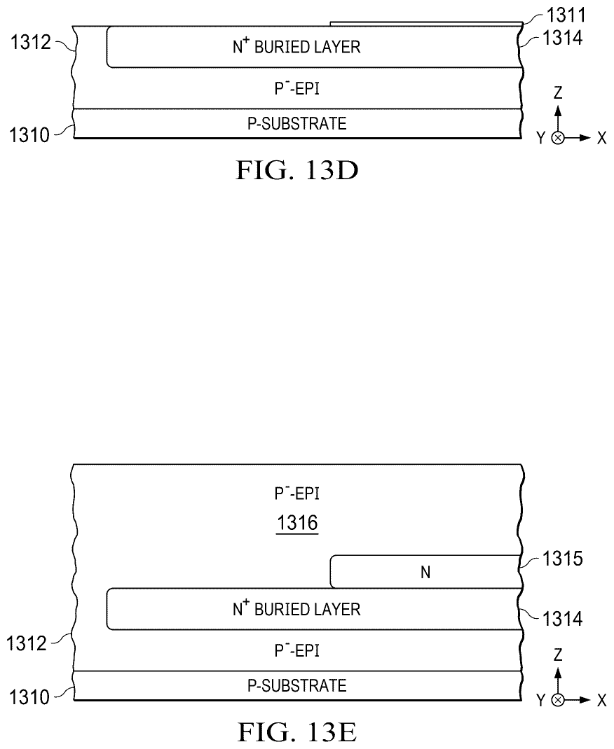

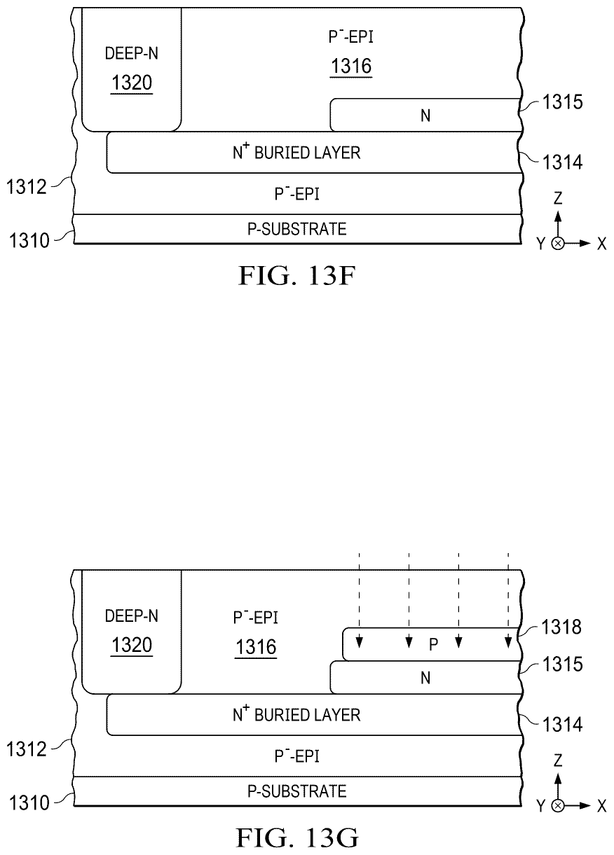

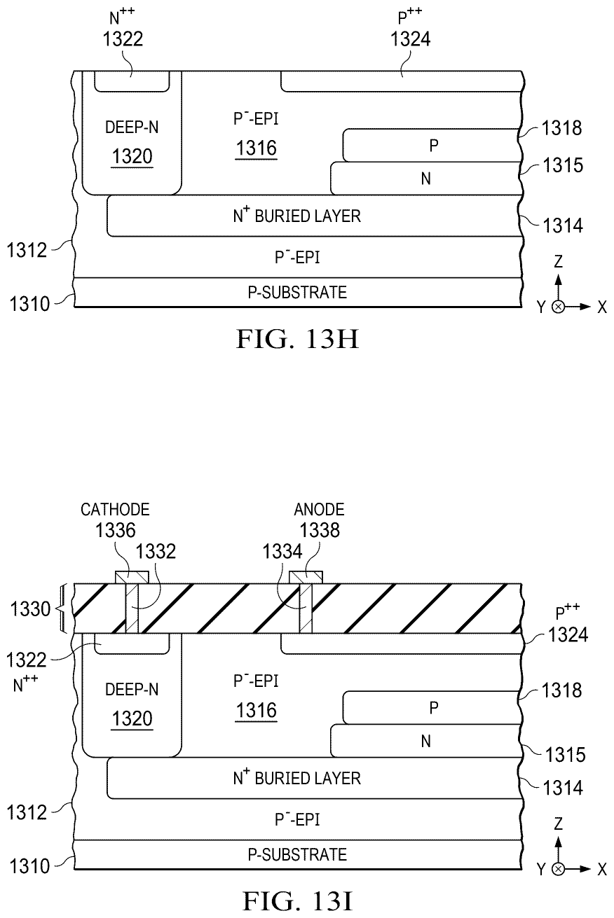

FIGS. 13A-13I illustrate an example of a process of fabricating an APD according to flowchart 1200 of FIG. 12. FIG. 13A illustrates an example of a semiconductor wafer or die including a p-type substrate 1310 and a lightly doped p-type epitaxial (p⁻ epi) layer 1312 grown on p-type substrate 1310. The semiconductor wafer or die shown in FIG. 13A may be fabricated using operations described above with respect to block 1210 of FIG. 12. P-type substrate 1310 and p⁻ epi layer 1312 may include a same base semiconductor material. In one example, p-type substrate 1310 may be a single crystalline silicon wafer doped with boron, and p⁻ epi layer 1312 may be a silicon epitaxial layer with boron incorporated during or after the epitaxial growth.

FIG. 13B illustrates an example of a heavily doped n-type (n⁺) region 1313 formed at a surface region of p⁻ epi layer 1312. N⁺ region 1313 may be formed using a mask and operations described above with respect to, for example, block 1220 of FIG. 12. The n-type dopants in n⁺ region 1313 may include, for example, As, Sb, or a combination thereof, and may be incorporated into p⁻ epi layer 1312 by diffusion or one or more ion implanting processes.

FIG. 13C shows that the semiconductor wafer or die may optionally be annealed at an elevated temperature (e.g., about 1150° C. to about 1225° C.) for a time period (e.g., at least about 30 minutes) as described above with respect to block 1220 of FIG. 12, such that the implanted n-type dopants in n⁺ region 1313 may diffuse deeper into p⁻ epi layer 1312 to form an n⁺ buried layer 1314.

FIG. 13D shows that a second n-type dopant (e.g., phosphorous) having a higher diffusion constant than the first n-type dopant (e.g., antimony) may be implanted into a region 1311 of n⁺ buried layer 1314 using an implant mask, as described above with respect to block 1230 of FIG. 12. The energy and dose of the second n-type dopant may be determined based on, for example, the thickness of a second p⁻ epi layer grown on p⁻ epi layer 1312, the target reverse bias voltage for avalanche multiplication, the total thermal budget of subsequent processes that may cause phosphorous to diffuse, and the like. For example, when the dose of the second n-type dopant is higher, the reverse bias voltage for avalanche multiplication may be lower. In one example, phosphorus may be implanted into region 1311 of n⁺ buried layer 1314 at a dose between about 2.8×10¹⁴ cm⁻² and about 4.2×10¹⁴ cm⁻² and an energy between about 160 keV and about 200 keV.

In FIG. 13E, a p⁻ epi layer 1316 may be grown on p⁻ epi layer 1312 and n⁺ buried layer 1314 as described above with respect to, for example, block 1240 of FIG. 4. P⁻ epi layer 1316 may include silicon and may include p-type impurities (e.g., boron) incorporated during or after the epitaxial growth of p⁻ epi layer 1316. Therefore, n⁺ buried layer 1314 may be buried between p⁻ epi layer 1312 and p⁻ epi layer 1316. During the epitaxial growth, the n-type dopants in n⁺ buried layer 1314 may diffuse deeper into p⁻ epi layer 1312 and p⁻ epi layer 1316, due to the elevated temperature during the epitaxial growth. In some examples, the semiconductor wafer or die may be annealed at an elevated temperature (e.g., between about 1125° C. and about 1200° C.) for a time period (e.g., at least about 120 minutes), during which the n-type dopants in n⁺ buried layer 1314 may diffuse deeper into p⁻ epi layer 1312 and p⁻ epi layer 1316. The second n-type dopant (e.g., P) in n⁺ buried layer 1314 may diffuse from the heavily doped n⁺ buried layer 1314 into p⁻ epi layer 1316 at a faster rate than the first n-type dopant (e.g., Sb). Therefore, a region of the lightly doped p⁻ epi layer 1316 adjacent to region 1311 of n⁺ buried layer 1314 may have a higher concentration of n-type dopants (e.g., mostly the second n-type dopant) than p-type dopants. As such, the region of p⁻ epi layer 1316 adjacent to region 1311 of n⁺ buried layer 1314 may become an n-type extension layer 1315. By selecting the proper dose and energy for implanting the second n-type dopant, the target impurity concentration profile and layer thickness and location of n-type extension layer 1315 may be achieved to achieve the target APD performance.

In FIG. 13F, at least one deep n contact 1320 may be formed in p⁻ epi layer 1316 and in contact with an edge region of n⁺ buried layer 1314. Deep n contact 1320 may be formed using, for example, operations described above with respect to block 1250 of FIG. 12. Deep n contact 1320 may include, for example, a deep n-well formed by implant and anneal processes, or a deep trench with a self-aligned sinker along sidewalls of the deep trench and an electrically conductive material (e.g., polysilicon) filling the deep trench as described above.

FIG. 13G shows that p-type dopants such as boron may be implanted into a region of p⁻ epi layer 1316 from the top surface of p⁻ epi layer 1316, for example, using an implant mask (not shown), as described above with respect to, for example, block 1260 of FIG. 12. The energy and dose of the p-type dopants may be selected such that the p-type dopants may penetrate into a region of p⁻ epi layer 1316 to form a p-type multiplication layer 1318 that is close to n-type extension layer 1315, thereby forming a PN junction between p-type multiplication layer 1318 and n-type extension layer 1315. In some examples, the semiconductor wafer or die may be annealed so that some p-type dopants in p-type multiplication layer 1318 may diffuse towards n-type extension layer 1315 and/or some n-type dopants in n⁺ buried layer 1314 and n-type extension layer 1315 may diffuse further into p⁻ epi layer 1316 to form the PN junction.

FIG. 13H shows an n⁺⁺ (or n⁺) region 1322 formed in deep n contact 1320, and a p⁺⁺ (or p⁺) region 1324 formed in a region of p⁻ epi layer 1316 above p-type multiplication layer 1318, using operations described above with respect to, for example, block 1270 of FIG. 12. N⁺⁺ region 1322 may be formed by implantation or diffusion of an n-type dopant such as P, Sb, or As, and may be used as a low-resistance cathode contact. P⁺⁺ (or p⁺) region 1324 may be formed by implantation or diffusion of a p-type dopant such as boron, and may be used as a low-resistance anode contact. P⁺⁺ region 1324, a region of p⁻ epi 1316 below p⁺⁺ region 1324, p-type multiplication layer 1318, n-type extension layer 1315, and n⁺ buried layer 1314 may form a p⁺/p⁻/p/n/n⁺ junction structure of an APD.

FIG. 13I shows that electrical interconnects may be formed in or on one or more dielectric layer 1330 (e.g., silicon oxide layers) using BEOL processes described above with respect to, for example, block 1280 of FIG. 12. For example, a cathode 1336 may be electrically coupled to n⁺⁺ region 1322 through at least one via 1332 formed in a dielectric layer 1330, whereas an anode 1338 may be electrically coupled to an edge region of p⁺⁺ region 1324 through at least one via 1334 formed in dielectric layer 1330. As described above with respect to, for example, FIGS. 2, 3, and 11, CMOS circuits and/or LDMOS circuits may be fabricated on the semiconductor wafer or die using similar processes.

It is noted that the operations illustrated in FIGS. 12-13I provide particular processes for fabricating an APD. Other sequences of operations can also be performed according to alternative examples. For example, alternative examples may perform the operations in a different order. Moreover, the individual operations illustrated in FIGS. 12-13I can include multiple sub-operations that can be performed in various sequences as appropriate for the individual operation. Furthermore, some operations can be added or removed depending on the particular example. In some examples, two or more operations may be performed in parallel. One of ordinary skill in the art would recognize many variations, modifications, and alternatives.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of at least a part of Y and any number of other factors. If an action X is “based on” Y, then the action X may be based at least in part on at least a part of Y.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal,” “node,” “interconnection,” “pin,” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuitry. For example, a field effect transistor (“FET”) (such as an n-channel FET (NFET) or a p-channel FET (PFET)), a bipolar junction transistor (BJT—e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors or other types of device structure transistors. Furthermore, the devices may be implemented in/over a silicon substrate (Si), a silicon carbide substrate (SiC), a gallium nitride substrate (GaN) or a gallium arsenide substrate (GaAs).

References may be made in the claims to a transistor's control input and its current terminals. In the context of a FET, the control input is the gate, and the current terminals are the drain and source. In the context of a BJT, the control input is the base, and the current terminals are the collector and emitter.

References herein to a FET being “on” or “enabled” means that the conduction channel of the FET is present and drain current ID (or drain-to-source current I_{DS}) may flow through the FET. References herein to a FET being “off” or “disabled” means that the conduction channel is not present so drain current does not flow through the FET. An “off” FET, however, may have current flowing through the transistor's body-diode.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other examples, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description.

In this description, unless otherwise stated, “about,” “approximately” or “substantially” preceding a parameter means being within +/-10 percent of that parameter or, if the parameter is zero, a reasonable range of values around zero.

Terms “and” and “or,” as used herein, may include a variety of meanings that are also expected to depend at least in part upon the context in which such terms are used. Typically, “or” if used to associate a list, such as A, B, or C, is intended to mean A, B, and C, here used in the inclusive sense, as well as A, B, or C, here used in the exclusive sense. In addition, the term “one or more” as used herein may be used to describe any feature, structure, or characteristic in the singular or may be used to describe some combination of features, structures, or characteristics. However, it should be noted that this is merely an illustrative example and claimed subject matter is not limited to this example. Furthermore, the term “at least one of” if used to associate a list, such as A, B, or C, can be interpreted to mean A, B, C, or a combination of A, B, and/or C, such as AB, AC, BC, AA, ABC, AAB, ACC, AABBCCC, or the like.

Although various examples have been described in detail, it should be understood that various changes, substitutions, and alterations can be made therein without departing from the scope defined by the appended claims. The devices, structures, materials, and processes discussed above are examples. Various examples may omit, substitute, or add various procedures or components as appropriate. Also, features described with respect to certain examples may be combined in various other examples. Different aspects and elements of the examples may be combined in a similar manner. Also, technology evolves and, thus, many of the elements are examples that do not limit the scope of the disclosure to those specific examples.

Specific details are given in the description on order to provide a thorough understanding of the examples. However, examples may be practiced without these specific details. For example, well-known circuits, processes, systems, structures, and techniques may have been shown without unnecessary detail in order to avoid obscuring the examples. This description provides examples only, and is not intended to limit the scope, applicability, or configuration of the invention. Rather, the preceding description of the examples will provide those skilled in the art with an enabling description for implementing various examples. Various changes may be made in the function and arrangement of elements without departing from the spirit and scope of the present disclosure. Modifications are possible in the described examples, and other examples are possible, within the scope of the claims.

What is claimed is:

1. An integrated circuit comprising:
a first semiconductor layer;
a second semiconductor layer on the first semiconductor layer, the second semiconductor layer is more lightly doped than the first semiconductor layer;
an avalanche photodiode (APD) in a first region of the second semiconductor layer; and
a laterally-diffused metal-oxide-semiconductor (LDMOS) circuit in a second region of the second semiconductor layer.

2. The integrated circuit of claim 1, wherein the first semiconductor layer includes a p-type silicon layer or an n-type silicon layer.

3. The integrated circuit of claim 1, wherein the first and second semiconductor layers are of a first type, and wherein the APD comprises:
a first region of a second type in the second semiconductor layer;
a second region of the second type on a first area of the first region of the second type, the second region of the second type being more lightly doped than the first region of the second type;
a first region of the first type on the second region of the second type;
a second region of the first type on the first region of the first type, the second region of the first type being more lightly doped than the first region of the first type; and
a third region of the first type on the second region of the first type, the third region of the first type being more heavily doped than the first region of the first type.

4. The integrated circuit of claim 3, wherein the LDMOS circuit comprises:
a third region of the second type in the second region of the second semiconductor layer; and
an LDMOS transistor over the third region of the second type, the LDMOS transistor including a buried layer of the first type.

5. The integrated circuit of claim 4, wherein:
the first region of the second type and the third region of the second type have same dopants of the second type; and
the first region of the first type and the buried layer of the first type have same dopants of the first type.

6. The integrated circuit of claim 4, wherein the LDMOS circuit further comprises deep contact structures coupled to the third region of the second type and surrounding the LDMOS transistor.

7. The integrated circuit of claim 3, wherein the APD further comprises one or more deep contact structures coupled to one or more second areas of the first region of the first type, the one or more second areas surrounding the first area.

8. The integrated circuit of claim 1, further comprising a complementary metal-oxide-semiconductor (CMOS) circuit in the second semiconductor layer.

9. The integrated circuit of claim 8, wherein the CMOS circuit comprises a transimpedance amplifier, an input terminal of the transimpedance amplifier electrically coupled to a cathode or an anode of the APD.

10. A semiconductor device comprising:
a first semiconductor layer of a first type;
a second semiconductor layer of a second type on the first semiconductor layer;
a region of the first type at a first side of the second semiconductor layer and coupled to a first area of the first semiconductor layer;
a first region of the second type on the region of the first type; and
a second region of the second type at a second side of the second semiconductor layer, the second region of the second type being more heavily doped than the first region of the second type.

11. The semiconductor device of claim 10, wherein:
the first semiconductor layer includes first dopants of the first type and second dopants of the first type, the first dopants of the first type having a different diffusion property from the second dopants of the first type.

12. The semiconductor device of claim 11, wherein:
the region of the first type includes the second dopants of the first type; and
a peak concentration of the second dopants of the first type in the first semiconductor layer is greater than a peak concentration of the second dopants of the first type in the region of the first type.

13. The semiconductor device of claim 11, wherein:
the first dopants of the first type include antimony; and
the second dopants of the first type include phosphorus.

14. The semiconductor device of claim 10, further comprising:
one or more deep contact structures passing through the second semiconductor layer and coupled to the first semiconductor layer;
a first terminal coupled to the one or more deep contact structures; and
a second terminal coupled to the second region of the second type.

15. The semiconductor device of claim 14, wherein the one or more deep contact structures are coupled to one or more second areas of the first semiconductor layer, the one or more second areas surrounding the first area.

16. The semiconductor device of claim 10, wherein a thickness of the second semiconductor layer on the first semiconductor layer is greater than 1 μm.

17. The semiconductor device of claim 10, wherein:
the first semiconductor layer is n-type; and
the second semiconductor layer is p-type.

18. The semiconductor device of claim 10, wherein:
the first semiconductor layer is p-type; and
the second semiconductor layer is n-type.

19. The semiconductor device of claim 10, further comprising:
a semiconductor substrate of the second type; and
an epitaxial layer of the second type on the semiconductor substrate, the epitaxial layer being more lightly doped than the semiconductor substrate,
wherein the first semiconductor layer is on or in a region of the epitaxial layer.

20. The semiconductor device of claim 10, wherein the first semiconductor layer, the second semiconductor layer, the region of the first type, the first region of the second type, and the second region of the second type are part of a photodiode.

21. A method comprising:
forming, in a semiconductor layer of a first type, a first region of a second type, the first region including first dopants of the second type;
doping a second region in the first region of the second type with second dopants of the second type to form the second region of the second type, the second dopants of the second type having a different diffusion property from the first dopants of the second type;
growing an epitaxial layer of the first type over the semiconductor layer and the second region, wherein the second dopants of the second type in the second region at least partially diffuse into the epitaxial layer during the growing;
forming a first region of the first type in the epitaxial layer above the second region of the epitaxial layer; and
forming a second region of the first type in a the epitaxial layer, the second region of the first type being spaced from and more heavily doped than the first region of the first type.

22. The method of claim 21, further comprising annealing at least the first region of the second type and the epitaxial layer to cause diffusion of the second dopants of the second type from the second region to the epitaxial layer, to form a third region of the second type in the epitaxial layer.

23. The method of claim 21, wherein:
the first dopants of the second type include antimony; and
the second dopants of the second type include phosphorus.

24. The method of claim 21, wherein:
forming the first region of the second type in the semiconductor layer of the first type includes doping a first area of the semiconductor layer of the first type with the first dopants of the second type; and
the method further comprises, while doping the first area of the semiconductor layer with the first dopants of the second type o, doping a second area of the semiconductor layer with the first dopants of the second type to form a third region of the second type.

25. The method of claim 24, further comprising, while forming the first region of the first type, forming a buried layer of the first type in an area of the epitaxial layer that is above the third region of the second type.

26. The method of claim 25, further comprising forming a laterally-diffused metal-oxide-semiconductor (LDMOS) transistor on the buried layer of the first type.

27. The method of claim 21, further comprising forming a terminal that is electrically connected to the second region of the first type.

28. The method of claim 21, further comprising forming one or more deep contact structures in the epitaxial layer, the one or more deep contact structures coupled to the second region of the second type.

29. The method of claim 28, further comprising:
forming one or more doped regions in the one or more deep contact structures; and
forming a terminal that is electrically connected to the one or more doped regions.

30. The method of claim 21, further comprising growing the semiconductor layer of the first type on a substrate of the first type.

31. The method of claim 21, wherein:
the semiconductor layer of the first type includes a p-type semiconductor layer, and the first region includes an n-type region; or
the semiconductor layer of the first type includes an n-type semiconductor layer, and the first region includes a p-type region.
